(19) United States
(12) Patent Application Publication
(10) Pub. No.: US 2024/0276762 A1
(43) Pub. Date: Aug. 15, 2024

(54) ORGANIC LIGHT EMITTING DIODE AND ORGANIC LIGHT EMITTING DEVICE INCLUDING THE SAME

(71) Applicant: LG Display Co., Ltd., Seoul (KR)

(72) Inventors: Ju-Hyuk KWON, Paju-si (KR); Eun-Jung PARK, Paju-si (KR); Jang-Dae YOUN, Paju-si (KR); Yu-Jeong LEE, Paju-si (KR); Hyun-Jin CHO, Paju-si (KR); Jun-Su HA, Paju-si (KR)

(73) Assignee: LG Display Co., Ltd., Seoul (KR)

(21) Appl. No.: 18/399,302

(22) Filed: Dec. 28, 2023

(30) Foreign Application Priority Data
Jan. 30, 2023 (KR) 10-2023-0011628
Dec. 13, 2023 (KR) 10-2023-0180568

(51) Int. Cl. H10K 50/858; H10K 50/19

(52) U.S. Cl. CPC H10K 50/858; H10K 50/19; H10K 50/15; H10K 85/624; H10K 85/626; H10K 85/633; H10K 85/636; H10K 85/6574; H10K 85/6576

(57) ABSTRACT

An organic light emitting diode (OLED) and an organic light emitting device (e.g., a display device or a lighting device) thereof are described. The OLED comprises a first electrode, a second electrode, a first emitting part (including a first hole transporting layer (HTL) and a first emitting material layer (EML), positioned between the first and second electrodes); and a second emitting part (including a second EML and positioned between the first emitting part and the second electrode). The first EML is a blue EML, and the second EML includes at least one of a red EML and a blue EML. The first hole HTL includes a high refractive layer having a first refractive index, and a low refractive layer having a second refractive index, positioned between the high refractive layer and the first EML, where the second refractive index is smaller than the first refractive index.

### CROSS-REFERENCE TO RELATED APPLICATIONS

The present application claims priority, under 35 U.S.C. § 119, to Korean Patent Application Nos. 10-2023-0011628 and 10-2023-0180568 filed in the Republic of Korea on Jan. 30, 2023 and Dec. 13, 2023, respectively, which are hereby incorporated by reference in its entirety into the present application.

### BACKGROUND

### Technical Field

The present disclosure relates to an organic light emitting diode (OLED), and more specifically, to an OLED having high blue emitting efficiency and improved color viewing angle, as well as to an organic light emitting device including the same.

### Discussion of Related Art

As demand increases for flat panel display devices that occupy a small space, an organic light emitting display devices including an OLED has been a focus of recent research and development. An OLED emits light by injecting electrons from a cathode as an electron injection electrode, and holes from an anode as a hole injection electrode, into an emitting material layer (EML), where the electrons are combined with the holes, generating an exciton, and which emits light as it transitions from an excited state to a ground state.

An OLED has certain advantages. For instance, an OLED can be formed as a thin organic film less than 2000 Å, and the electrode configurations can implement unidirectional or bidirectional images. Also, the OLED can be formed on a flexible substrate. For example, a plastic substrate can be used as a base substrate where elements are formed. In addition, the organic light emitting display device can be operated at a voltage (e.g., 10V or below) lower than a voltage required to operate other display devices. Moreover, the organic light emitting display device has advantages in the power consumption and the color sense.

Recently, a white OLED including a blue EML, a red EML and a green EML is introduced. However, since the blue EML has an emitting efficiency lower than each of the red and green EML, there can be a limitation of low color temperature and low brightness in the white OLED. In addition, when a position of the EMLs is adjusted to improve the blue emitting efficiency, a color viewing angle of the white OLED can be decreased, which can reduce the performance of the OLED.

### SUMMARY OF THE INVENTION

Embodiments of the present disclosure are directed to an OLED and an organic light emitting device including the OLED that address one or more of the limitations and disadvantages of the related conventional art. An organic light-emitting diode and device thereof according to aspects of the present disclosure can operate at a low voltage, consume less power, render excellent colors, and/or can be used in a variety of applications.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is an organic light emitting diode comprising a first electrode: a second electrode facing the first electrode: a first emitting part comprising a first hole transporting layer and a first emitting material layer and positioned between the first and second electrodes; and a second emitting part comprising a second emitting material layer and positioned between the first emitting part and the second electrode, wherein the first emitting material layer is a blue emitting material layer, and the second emitting material layer comprises at least one of a red emitting material layer and a green emitting material layer, wherein the first hole transporting material layer comprises a high refractive layer having a first refractive index and a low refractive layer having a second refractive index and positioned between the high refractive layer and the first emitting material layer, and wherein the second refractive index is smaller than the first refractive index.

In certain embodiments, the OLED comprises a first electrode: a second electrode facing the first electrode: a first emitting part comprising a first hole transporting layer and a first emitting material layer and positioned between the first and second electrodes; and a second emitting part comprising a second emitting material layer and positioned between the first emitting part and the second electrode, where the first emitting material layer is a blue emitting material layer, and the second emitting material layer comprises at least one of a red emitting material layer and a blue emitting material layer, where the first hole transporting material layer comprises a high refractive layer having a first refractive index in a range of 1.9 to 2.0, and a low refractive layer having a second refractive index in a range of 1.7 to 1.8; and wherein the low refraction layer is positioned between the high refractive layer and the first emitting material layer. In certain aspects, the high refractive layer has a thickness in a range of 200 to 500 Å, and the low refractive layer has a thickness in a range of 500 to 800 Å. In certain aspects, the high refractive layer comprises a compound in Formula 1, as described herein, and the low refractive layer comprises a compound in Formula 2, as described herein.

Another aspect of the present disclosure is an organic light emitting device comprising a substrate and the above organic light emitting diode over the substrate.

It is to be understood that both the foregoing general description and the following detailed description are exemplary and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic circuit diagram illustrating an organic light emitting display device according to one or more embodiments of the present disclosure.

FIG. 2 is a schematic cross-sectional view illustrating an organic light emitting display device according to one or more embodiments of the present disclosure.

FIG. 3 is a schematic cross-sectional view illustrating an OLED according to one or more embodiments of the present disclosure.

FIG. 4 is a schematic cross-sectional view illustrating an OLED according to one or more embodiments of the present disclosure.

FIG. 5 is a schematic cross-sectional view illustrating an OLED according to one or more embodiments of the present disclosure.

FIG. 6 is a graph showing an EL (electroluminescence) spectrum of an OLED of Comparative Example 1.

FIG. 7 is a graph showing an EL spectrum of an OLED of Comparative Example 2.

FIG. 8 is a graph showing an EL spectrum of an OLED of Comparative Example 3.

FIG. 9 is a graph showing an EL spectrum of an OLED of Example 1.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example: however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts can be added unless ‘only’ is used. When a component is expressed in the singular, cases including the plural are included unless specific statement is described.

In construing an element, the element is construed as including an error or tolerance range, even if there is no explicit description of such an error or tolerance range.

In describing a position relationship, for example, when a position relation between two parts is described as, for example, “on,” “over,” “above,” “under,” “below,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included, unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically, as those skilled in the art can sufficiently understand. The aspects of the present disclosure can be carried out independently from each other, or can be carried out together in co-dependent relationship.

Reference will now be made in detail to some of the examples and preferred embodiments, which are illustrated in the accompanying drawings. All the components of each OLED and each organic light emitting display device according to all embodiments of the present disclosure are operatively coupled and configured.

In the present disclosure, an organic light emitting device including the OLED can be an organic light emitting display device or an organic lightening device, but can include other devices such as testing devices, medical devices, etc.

As an example, an organic light emitting display device, which is a display device including the OLED of the present disclosure, will be mainly described.

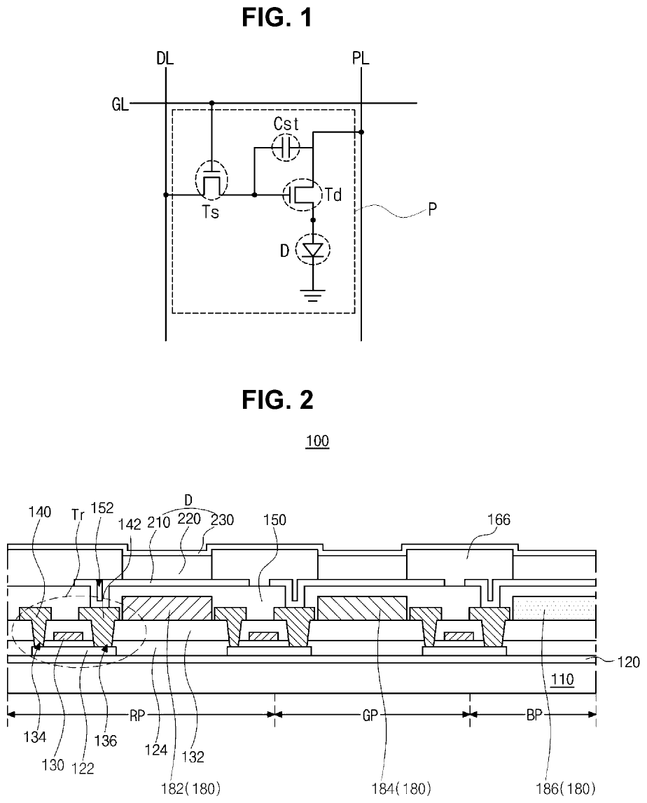

FIG. 1 is a schematic circuit diagram illustrating an organic light emitting display device according to an embodiment of the present disclosure.

As illustrated in FIG. 1, a gate line GL and a data line DL, which cross each other to define a pixel region (pixel) P, and a power line PL are formed in the organic light emitting display device. A switching thin film transistor (TFT) Ts, a driving TFT Td, a storage capacitor Cst and an OLED D are formed in the pixel region P. The pixel region P can include a red pixel region, a green pixel region and a blue pixel region, but other variations are possible. For instance, the pixel region P can include a red pixel region, a green pixel region, a blue pixel region and a white pixel region. The organic light emitting display device includes a plurality of such pixel regions P which can be arranged in a matrix configuration or other suitable configuration. The organic light emitting display device can further include other components such as a timing controller, a scan driver, a data driver, a power source, etc., and can be a flexible, bendable, or wearable device, which can include a touch function.

In each pixel region P, the switching thin film transistor Ts is connected to the gate line GL and the data line DL, and the driving thin film transistor Td is connected between the switching thin film transistor Ts and the power line PL. The storage capacitor Cst is connected to a gate electrode and a drain electrode of the driving TFT Td, and the OLED D is connected to the driving thin film transistor Td.

When the switching thin film transistor Ts is turned on by the gate signal (scan signal) applied through the gate line GL (scan line), the data signal applied through the data line DL is applied into the gate electrode of the driving thin film transistor Td and one electrode of the storage capacitor Cst through the switching thin film transistor Ts.

The driving thin film transistor Td is turned on by the data signal applied into the gate electrode so that a current proportional to the data signal is supplied from the power line PL to the OLED D through the driving thin film transistor Td. The OLED D emits light having a luminance proportional to the current flowing through the driving thin film transistor Td. In this case, the storage capacitor Cst is charge with a voltage proportional to the data signal so that the voltage of the gate electrode in the driving thin film transistor Td is kept constant during one frame. Therefore, the organic light emitting display device can display a desired image by driving the OLEDs in the pixel regions P.

FIG. 2 is a schematic cross-sectional view illustrating an organic light emitting display device according to a first embodiment of the present disclosure.

As illustrated in FIG. 2, an organic light emitting display device 100 includes a substrate 110, where a red pixel region RP, a green pixel region GP and a blue pixel region BP are defined, a TFT Tr disposed over the substrate 110, an OLED D, which is disposed over the TFT Tr and connected to the TFT Tr, and a color filter layer 180 between the OLED D and the substrate 110. The pixel configuration of the organic light emitting display device 100 can correspond to that of FIG. 1, but is not limited thereto. Obviously, so many variations of the organic light emitting display device 100 can be possible, e.g., a white pixel region WP can be further included.

The substrate 110 can be a glass substrate or a flexible substrate. For example, the substrate 110 can be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 120 is formed on the substrate, and the TFT Tr corresponding to each of the red, green and blue pixel regions RP, GP and BP is formed on the buffer layer 120. The buffer layer 120 can be omitted, in certain embodiments. In this case, the TFT Tr can be disposed on the substrate 110.

A semiconductor layer 122 is formed on the buffer layer 120. The semiconductor layer 122 can include an oxide semiconductor material or polycrystalline silicon. When the semiconductor layer 122 includes the oxide semiconductor material, a light-shielding pattern can be formed under the semiconductor layer 122. The light to the semiconductor layer 122 is shielded or blocked by the light-shielding pattern such that thermal degradation of the semiconductor layer 122 can be prevented. On the other hand, when the semiconductor layer 122 includes polycrystalline silicon, impurities can be doped into both sides of the semiconductor layer 122.

A gate insulating layer 124 of an insulating material is formed on the semiconductor layer 122. The gate insulating layer 124 can be formed of an inorganic insulating material such as silicon oxide (SiOx) or silicon nitride (SiNx).

A gate electrode 130, which is formed of a conductive material, e.g., metal, is formed on the gate insulating layer 124 to correspond to a center of the semiconductor layer 122. In FIG. 2, the gate insulating layer 124 is formed on the entire surface of the substrate 110. Alternatively, the gate insulating layer 124 can be patterned to have the same shape as the gate electrode 130.

An interlayer insulating layer 132, which is formed of an insulating material, is formed on the gate electrode 130. The interlayer insulating layer 132 can be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 122. The first and second contact holes 134 and 136 are positioned at both sides of the gate electrode 130 to be spaced apart from the gate electrode 130. The first and second contact holes 134 and 136 are formed through the gate insulating layer 124 and the interlayer insulating layer 132. Alternatively, when the gate insulating layer 124 is patterned to have the same shape as the gate electrode 130, the first and second contact holes 134 and 136 is formed only through the interlayer insulating layer 132.

A source electrode 140 and a drain electrode 142, which are formed of a conductive material, e.g., metal, are formed on the interlayer insulating layer 132. The source electrode 140 and the drain electrode 142 are spaced apart from each other with respect to the gate electrode 130 and respectively contact both sides of the semiconductor layer 122 through the first and second contact holes 134 and 136. In certain embodiments, the designation of the source and drain electrodes 140 and 142 can be switched with each other depending on the type and configuration of a transistor.

The semiconductor layer 122, the gate electrode 130, the source electrode 140 and the drain electrode 142 constitute the TFT Tr, and the TFT Tr can be an n-type TFT, but can be a p-type TFT. The TFT Tr serves as a driving element. Namely, the TFT Tr can correspond to the driving TFT Td (of FIG. 1).

In the TFT Tr, the gate electrode 130, the source electrode 140, and the drain electrode 142 are positioned over the semiconductor layer 122. Namely, the TFT Tr has a coplanar structure. Alternatively, in the TFT Tr, the gate electrode can be positioned under the semiconductor layer, and the source and drain electrodes can be positioned over the semiconductor layer such that the TFT Tr can have an inverted staggered structure. In this instance, the semiconductor layer can include amorphous silicon.

The color filter layer 180 is formed on the interlayer insulating layer 132. The color filter layer 180 includes red, green and blue color filters 182, 184 and 186 respectively corresponding to the red, green and blue pixel regions RP, GP and BP.

The red color filter 182 can include at least one of a red dye and a red pigment, the green color filter 184 can include at least one of a green dye and a green pigment, and the blue color filter 186 can include at least one of a blue dye and a blue pigment.

In certain embodiments, the gate line and the data line cross each other to define the pixel region, and the switching TFT is formed to be connected to the gate and data lines. The switching TFT is connected to the TFT Tr as the driving element. In addition, the power line, which can be formed to be parallel to and spaced apart from one of the gate and data lines, and the storage capacitor for maintaining the voltage of the gate electrode of the TFT Tr in one frame can be further formed.

A planarization layer 150 is formed on the color filter layer 180 and the TFT Tr. The planarization layer 150 has a flat top surface and includes a drain contact hole 152 exposing the drain electrode 142 of the TFT Tr.

The OLED D is disposed on the planarization layer 150 and includes a first electrode 210, which is connected to the drain electrode 142 of the TFT Tr, an organic emitting layer 220 on the first electrode 210 and a second electrode 230 on the organic emitting layer 220. The OLED D is disposed at each of the red, green and blue pixel regions and emits white light.

The first electrode 210 is separately formed in each pixel region. The first electrode 210 can be an anode and can be formed of a conductive material having a relatively high work function. The first electrode 210 can be a transparent electrode. For example, the first electrode 210 can be formed of a conductive material having a relatively high work function, e.g., a transparent conductive oxide (TCO). For example, the first electrode 210 can include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO).

A bank layer 166 is formed on the planarization layer 150 to cover an edge of the first electrode 210. For instance, the bank layer 166 is positioned at a boundary of the pixel region and exposes a center of the first electrode 210 in the pixel region. Since the OLED D emits white light in the red, green and blue pixel regions RP, GP and BP, the organic light emitting layer 220 can be continuously formed as a common layer in the red, green and blue pixel regions RP, GP and BP without separation. The bank layer 166 can be formed to prevent a current leakage at an end of the first electrode 210. The bank layer 166 can be omitted, in certain embodiments.

The organic emitting layer 220 is formed on the first electrode 210. The organic emitting layer 220 can include a first emitting part including a first blue emitting material layer (EML) and a first hole transporting layer (HTL) and a second emitting part including at least one of a green EML and a red EML and between the first emitting part and the second electrode 230.

In an aspect of the present disclosure, the organic emitting layer 220 can further include a third emitting part including a blue EML and between the second emitting part and the second electrode 230.

In an aspect of the present disclosure, the second emitting part includes the green EML, and the organic emitting layer 220 can further include a third emitting part including a blue EML and between the second emitting part and the second electrode 230 and a fourth emitting part including a red EML and between the first emitting part and the first electrode 210.

The second electrode 230 is formed over the substrate 110 where the organic emitting layer 220 is formed. The second electrode 230 covers an entire surface of the display area and can be formed of a conductive material having a relatively high reflectance. For example, the second electrode 230 can be formed of a material having high reflectance, such as aluminum (Al), magnesium (Mg), calcium (Ca), silver (Ag), their alloys or their combinations.

In the OLED D of the present disclosure, the first electrode 210 can be a transparent electrode, and the second electrode 230 can be a reflective electrode.

An encapsulation layer (or encapsulation film) can be formed on the second electrode 230 to prevent penetration of moisture into the OLED D. The encapsulation film can include a first inorganic insulating layer, an organic insulating layer and a second inorganic insulating layer sequentially stacked, but it is not limited thereto.

A metal plate can be disposed on the encapsulation layer, but other layers can be formed instead.

The organic light emitting display device 100 can further include a polarization plate for reducing an ambient light reflection. For example, the polarization plate can be a circular polarization plate.

In FIG. 2, the color filter layer 180 is disposed between the OLED D and the interlayer insulating layer 132. Alternatively, the color filter layer 180 can be disposed at any position between the OLED D and the substrate 110.

The organic light emitting display device 100 can include a color conversion layer between the OLED D and the color filter layer 180. The color conversion layer includes red, green and blue color conversion layers respectively corresponding to the red, green and blue pixel regions RP, GP and BP, and the white light from the OLED D can be converted into red, green and blue light.

As described above, the white light from the OLED D passes through the red, green and blue color filters 182, 184 and 186 respectively disposed in the red, green and blue pixel regions RP, GP and BP so that red, green and blue light can be displayed in the red, green and blue pixel regions RP, GP and BP.

In FIG. 2, the OLED D emitting the white light is used for a display device. Alternatively, the OLED D can be formed on an entire surface of a substrate without at least one of the driving element and the color filter layer to be used for a lightening device. The display device and the lightening device each including the OLED D of the present disclosure can be referred to as an organic light emitting device.

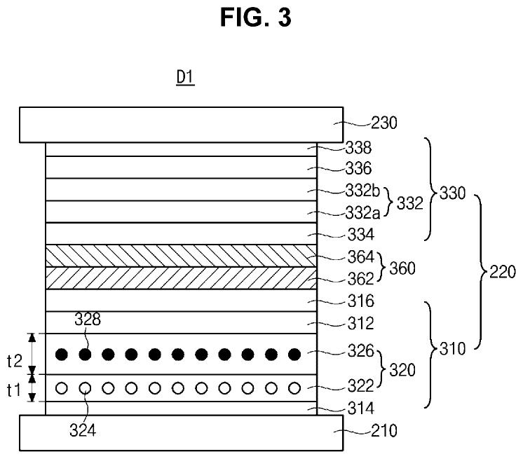

FIG. 3 is a schematic cross-sectional view illustrating an example of an OLED according to an embodiment of the present disclosure. The OLED configuration of FIG. 3 can be used as the OLED of FIGS. 1 and 2 or other figures or embodiments of the present disclosure.

As shown in FIG. 3, the OLED D1 includes the first and second electrodes 210 and 230, which face each other, and the organic emitting layer 220 therebetween, and the organic emitting layer 220 includes a first emitting part 310 including a first hole transport layer (HTL) 320, which includes a high refractive layer 322 and a low refractive layer 326, and a first emitting material layer (EML) 312, which is a blue EML, and a second emitting part 330 including a second EML 332, which includes a red EML 332a and a green EML 332b, and positioned between the first emitting part 310 and the second electrode 230.

The organic emitting layer 220 can further include a charge generation layer (CGL) 360 between the first and second emitting parts 310 and 330.

The organic light emitting display device 100 includes the red, green and blue pixel regions RP, GP and BP, and the OLED D1 is positioned in each of the red, green and blue pixel regions RP, GP and BP and emits white light.

In the first emitting part 310, the first HTL 320 has a double-layered structure of the high refractive layer 322 and a low refractive layer 326, and the low refractive layer 326 is positioned between the high refractive layer 322 and the first EML 312. The low refractive layer 326 can contact the high refractive layer 322 and the first EML 312.

The high refractive layer 322 includes a first hole transporting material 324 having a first refractive index, and the low refractive layer 326 includes a second hole transporting material 328 having a second refractive index smaller than the first refractive index. A difference between the first and second refractive indexes can be 0.05 or more. In an aspect of the present disclosure, a difference between the first and second refractive indexes can be 0.05 or more and 0.25 or less, e.g., 0.09 or more and 0.25 or less, beneficially 0.1 or more and 0.25 or less, and more beneficially 0.15 or more and 0.25 or less. For example, the first refractive index can be in a range of 1.9 to 2.1, and the second refractive index can be in a range of 1.7 to 1.9.

In an aspect of the present disclosure, the first hole transporting material 324 can be at least one of a compound in Formula 1 and a compound in Formula 2, and the second hole transporting material 328 can be at least one of a compound in Formula 2, a compound in Formula 3, a compound in Formula 4 and a compound in Formula 5. The first first hole transporting material 324 and the second hole transporting material 328 are different from each other.

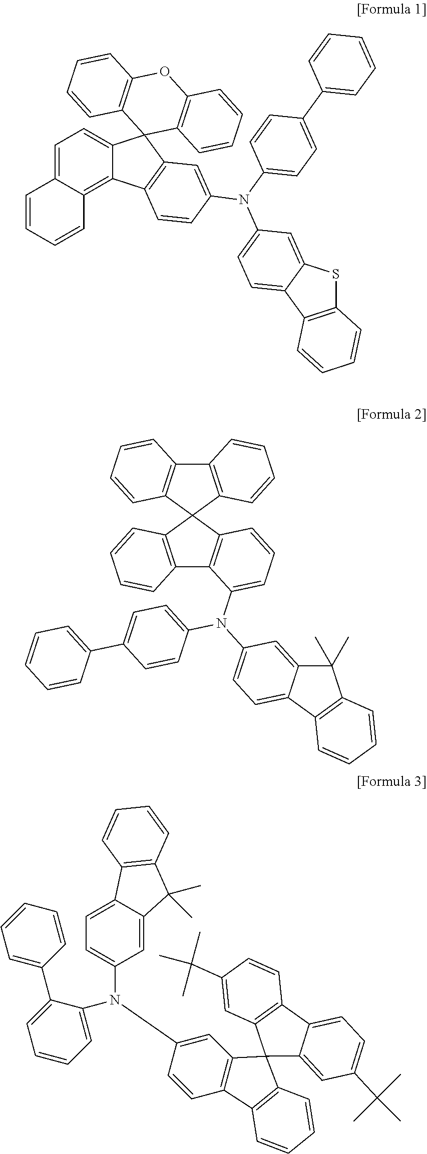 [SMILES: c1ccc(-c2ccc(N(c3ccc4c(c3)C3(c5ccccc5Oc5ccccc53)c3ccc5ccccc5c3-4)c3ccc4c(c3)sc3ccccc34)cc2)cc1 ; CC1(C)c2ccccc2-c2ccc(N(c3ccc(-c4ccccc4)cc3)c3cccc4c3-c3ccccc3C43c4ccccc4-c4ccccc43)cc21 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

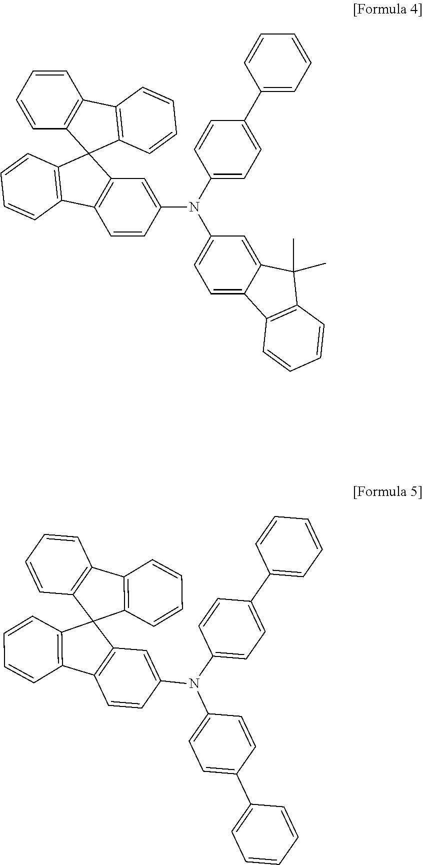 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(N(c3ccc(-c4ccccc4)cc3)c3ccc4c(c3)C3(c5ccccc5-c5ccccc53)c3ccccc3-4)cc2)cc1]

A refractive index of the compounds in Formulas 1 to 5 was measured and listed in Table 1.

A material layer with a thickness of 300 Å was formed on a bare glass by depositing a compound in a chamber with a condition of 1.0*10-6 torr or less in a deposition rate of 1.0 Å/s, and a refractive index of the material layer was measured by using a RC2 Ellipsometer (J. A Woollam) apparatus. A “psi” value and a “delta” value were measured in a wavelength range of 210 to 1000 nm and an angle of 50 to 70° with 5° intervals to obtain a refractive index according to a wavelength. To increase the accuracy of the measured refractive index, the transmittance was measured in the range of 0 to 60° with 20° intervals. The refractive index was calculated by modeling the measured “pai” value and “delta” value. The refractive index in Table 1 is a value in 450 nm.

TABLE 1

| Compound | Formula 1 | Formula 2 | Formula 3 | Formula 4 | Formula 6 |
|---|---|---|---|---|---|
| Refractive | 2.01 | 1.91 | 1.75 | 1.87 | 1.87 |
| index | | | | | |

In an aspect of the present disclosure, the first hole transporting material 324 can be the compound in Formula 1. Namely, the high refractive layer 322 can be formed by only the compound in Formula 1.

In an aspect of the present disclosure, the first hole transporting material 324 can include the compound in Formula 1 and the compound in Formula 2. In this case, a weight % of the compound in Formula 1 can be equal to or greater than that of the compound in Formula 2. For example, a weight % ratio of the compound in Formula 2 to the compound in Formula 1 can be 5:5 to 9:1, e.g., 6:4, 7:3 or 8:2.

In an aspect of the present disclosure, the second hole transporting material 328 can include only the compound in Formula 3. Namely, the low refractive layer 326 can be formed by only the compound in Formula 3.

In an aspect of the present disclosure, the second hole transporting material 328 can include only the compound in Formula 4. Namely, the low refractive layer 326 can be formed by only the compound in Formula 4.

In an aspect of the present disclosure, the second hole transporting material 328 can include only the compound in Formula 5. Namely, the low refractive layer 326 can be formed by only the compound in Formula 5.

In an aspect of the present disclosure, the second hole transporting material 328 can include at least two of the compound in Formula 2, the compound in Formula 3, the compound in Formula 4 and the compound in Formula 5.

In an aspect of the present disclosure, the second hole transporting material 328 can include the compound in Formula 2 and the compound in Formula 4. In this case, a weight % of the compound in Formula 2 and a weight % of the compound in Formula 4 can be same or different. For example, the low refractive layer 326 can be formed by co-depositing the compound in Formula 2 and the compound in Formula 4.

In an aspect of the present disclosure, the second hole transporting material 328 can include the compound in Formula 4 and the compound in Formula 5. In this case, a weight % of the compound in Formula 4 and a weight % of the compound in Formula 5 can be same or different. For example, the low refractive layer 326 can be formed by co-depositing the compound in Formula 4 and the compound in Formula 5.

In an aspect of the present disclosure, the second hole transporting material 328 can include the compound in Formula 2 and the compound in Formula 5. In this case, a weight % of the compound in Formula 2 and a weight % of the compound in Formula 5 can be same or different. For example, the low refractive layer 326 can be formed by co-depositing the compound in Formula 2 and the compound in Formula 5.

In an aspect of the present disclosure, the first hole transporting material 324 can include at least one of the compound in Formula 1 and the compound in Formula 2, and the second hole transporting material 328 can include at least one of the compound in Formula 3, the compound in Formula 4 and the compound in Formula 5.

The high refractive layer 322 can have a first thickness t1, and the low refractive layer 326 can have a second thickness t2 being greater than the first thickness t1. The first thickness t1 of the high refractive layer 322 can be 10 to 49% of a thickness of the first HTL 320, and the second thickness t2 of the low refractive layer 326 can be 51 to 90% of the thickness of the first HTL 320. In an aspect of the present disclosure, the first thickness of the high refractive layer 322 can be 20 to 45%, e.g., 30 to 45%, of the thickness of the first HTL 320.

In certain embodiments, the first thickness t1 can be 200 Å, 225 Å, 250 Å, 275 Å, 300 Å, 325 Å, 350 Å, 375 Å, 400 Å, 425 Å, 450 Å, 475 Å, or 500 Å. In certain embodiments, the second thickness t2 can be 500 Å, 525 Å, 550 Å, 575 Å, 600 Å, 625 Å, 650 Å, 675 Å, 700 Å, 725 Å, 750 Å, 775 Å, or 800 Å. For example, the first thickness t1 can be 200 to 500 Å, (e.g., 250 to 450 Å, 300 to 450 Å, 250 to 400 Å, or 300 to 400 Å) and the second thickness t2 can be 500 to 800 Å, (e.g., 500 to 750 Å, 550 to 750 Å, or 550 to 700 Å).

The first EML 312 is a blue EML and can include a blue host and a blue dopant. The blue dopant can include at least one of a fluorescent compound, a phosphorescent compound and a delayed fluorescent compound. In an aspect of the present disclosure, the blue dopant can be a fluorescent compound.

For example, the blue host can be selected from the group consisting of mCP, 9-(3-(9H-carbazol-9-yl)phenyl)-9H-carbazole-3-carbonitrile (mCP-CN), 3,3′-bis(N-carbazolyl)-1,1′-biphenyl (mCBP), CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), diphenyl-4-triphenylsilyl-phenylphosphine oxide (TSPO1), 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spiorobifluoren-2-yl-diphenyl-phosphine oxide (SPPOI), 9,9′-(5-(triphenylsilyl)-1,3-phenylene)bis(9H-carbazole) (SimCP), and mixtures thereof.

The blue dopant can be selected from the group consisting of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spiorfluorene (spiro-DPVBi), [1,4-bis[2-[4-[N,N-di(p-tolyl)amino]phenyl]vinyl] benzene (DSB), 1,4-di-[4-(N,N-diphenyl)amino]styryl-benzene (DSA), 2,5,8,11-tetra-tetr-butylperylene (TBPe), bis(2-hydroxylphenyl)-pyridine)beryllium (Bepp2), 9-(9-Phenylcarbazole-3-yl)-10-(naphthalene-1-yl)anthracene (PCAN), mer-tris(1-phenyl-3-methylimidazolin-2-ylidene-C,C(2)′ iridium(III) (mer-Ir(pmi)3), fac-tris(1,3-diphenyl-benzimidazolin-2-ylidene-C,C(2)′iridium(III) (fac-Ir(dpbic)3), bis(3,4,5-trifluoro-2-(2-pyridyl)phenyl-(2-carboxypyridyl)iridium(III)(Ir(tfpd)2pic), tris(2-(4,6-difluorophenyl)pyridine))iridium(III) (Ir(Fppy)3), bis[2-(4,6-difluorophenyl)pyridinato-C2,N](picolinato)iridium(III) (FIrpic), and mixtures thereof.

The first emitting part 310 can further include a first electron transporting layer (ETL) 316 over the first EML 312. In addition, the first emitting part 310 can further include a hole injection layer (HIL) 314 under the first HTL 320.

For example, the first emitting part 310 can include the HIL 314, the first HTL 320, the first EML 312 and the first ETL 316 sequentially stacked on the first electrode 210, and the high refractive layer 322 can be disposed between the HIL 314 and the low refractive layer 326.

In the second emitting part 330, the green EML 332b can be positioned between the red EML 332a and the second electrode 230.

The red EML 332a can include a red host and a red dopant. The red host can include a p-type host and an n-type host, and the red dopant can include at least one of a fluorescent compound, a phosphorescent compound and a delayed fluorescent compound. In an aspect of the present disclosure, the red dopant can be a phosphorescent compound.

For example, the red host can include at least one selected from the group consisting of mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-bipheyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbipheyl (CDBP), 2,7-bis(carbazole-9-yl)-9,9-dimethylfluorene (DMFL-CBP), 2,2′, 7,7′-tetrakis(carbazole-9-yl)-9,9-spiorofluorene (Spiro-CBP), 3,6-bis(carbazole-9-yl)-9-(2-ethyl-hexyl)-9H-carbazole (TCz1), and mixtures thereof.

The red dopant can be selected from the group consisting of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)2(acac)), tris[2-(4-n-hexylphenyl)quinoline]iridium(III) (Hex-Ir(phq)3), tris[2-phenyl-4-methylquinoline]iridium(III) (Ir(Mphq)3), bis(2-phenylquinoline)(2,2,6,6-tetramethylheptene-3,5-dionate)iridium(III) (Ir(dpm)PQ2), bis(phenylisoquinoline)(2,2,6,6-tetramethylheptene-3,5-dionate)iridium(III) (Ir(dpm)(piq)2), bis[(4-n-hexylphenyl)isoquinoline](acetylacetonate)iridium(III) (Hex-Ir(piq)2(acac)), tris[2-(4-n-hexylphenyl)quinoline]iridium(III) (Hex-Ir(piq)3), tris(2-(3-methylphenyl)-7-methyl-quinolato)iridium (Ir(dmpq)3), bis[2-(2-methylphenyl)-7-methyl-quinoline](acetylacetonate)iridium(III) (Ir(dmpq)2(acac)), bis[2-(3,5-dimethylphenyl)-4-methyl-quinoline](acetylacetonate)iridium((Ir(mphmq)2(acac)), tris(dibenzoylmethane)mono(1,10-phenanthroline)europium(III) (Eu(dbm)3(phen)), and mixtures thereof.

The green EML 332b can include a green host and a green dopant. The green host can include a p-type host and an n-type host, and the green dopant can include at least one of a fluorescent compound, a phosphorescent compound and a delayed fluorescent compound. In an aspect of the present disclosure, the green dopant can be a phosphorescent compound.

For example, the green host can include at least one selected from the group consisting of mCP-CN, CBP, mCBP, mCP, DPEPO, 2,8-bis(diphenylphosphoryl)dibenzothiophene (PPT), TmPyPB, PYD-2Cz, 2,8-di(9H-carbazol-9-yl)dibenzothiophene (DCzDBT), 3′, 5′-di(carbazol-9-yl)-[1,1′-bipheyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), and mixtures thereof.

The green dopant can include at least one selected from the group consisting of [bis(2-phenylpyridine)](pyridyl-2-benzofuro[2,3-b]pyridine)iridium, tris [2-phenylpyridine]iridium(III) (Ir(ppy)3), fac-tris(2-phenylpyridine)iridium(III) (fac-Ir(ppy)3), bis(2-phenylpyridine)(acetylacetonate)iridium(III) (Ir(ppy)2(acac)), tris [2-(p-II) (Ir(mppy)3), bis(2-(naphthalene-2-tolyl)pyridine]iridium(yl)pyridine)(acetylacetonate)iridium(III) (Ir(npy)2acac), tris(2-phenyl-3-methyl-pyridine)iridium (Ir(3mppy)3), fac-tris(2-(3-p-xylyl)phenyl)pyridine iridium(III) (TEG), and mixtures thereof.

The second EML 330 can further include a yellow-green EML between the red and green EMLs 332a and 332b.

The yellow-green EML can include a yellow-green host and a yellow-green dopant. The yellow-green host can include a p-type host and an n-type host, and the yellow-green dopant can include at least one of a fluorescent compound, a phosphorescent compound and a delayed fluorescent compound. In an aspect of the present disclosure, the yellow-green dopant can be a phosphorescent compound.

The yellow-green host can be selected from materials of the above-mentioned green host.

The yellow-green dopant can include at least one selected from the group consisting of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)irdium(III) (Ir(BT)2(acac)), bis(2-(9,9-diethytl-fluoren-2-yl)-1-phenyl-1H-benzo[d]imdiazolato)(acetylacetonate)iridium(III) (Ir(fbi)2(acac)), bis(2-phenylpyridine)(3-(pyridine-2-yl)-2H-chromen-2-onate)iridium(III) (fac-Ir(ppy)2Pc), bis(2-(2,4-difluorophenyl)quinoline)(picolinate)iridium(MI) (FPQIrpic), bis(4-phenylthieno[3,2-c]pyridinato-N,C2′) (acetylacetonate) iridium(III) (PO-01), and mixtures thereof.

The second emitting part 330 can further include a second HTL 334 under the second EML 332. The second emitting part 330 can further include at least one of a second ETL 336 over the second EML 332 and an electron injection layer (EIL) 338 over the second ETL 336.

For example, the second emitting part 330 can include the second HTL 334, the second EML 332, the second ETL 336 and the EIL 338 sequentially stacked on the CGL 360.

The HIL 314 can include a hole injection material being selected from the group consisting of 4,4′,4″-tris(3-methylphenylamino)triphenylamine (MTDATA), 4,4′,4″-tris(N,N-diphenyl-amino)triphenylamine (NATA), 4,4′, 4″-tris(N-(naphthalene-1-yl)-N-phenyl-amino)triphenylamine (IT-NATA), 4,4′, 4″-tris(N-(naphthalene-2-yl)-N-phenyl-amino)triphenylamine (2T-NATA), copper phthalocyanine(CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile(dipyrazino[2,3-f:2′ 3′-h]quinoxaline-2,3,6,7,10,11-hexacarbonitrile (HAT-CN), 1,3,5-tris[4-(diphenylamino)phenyl]benzene (TDAPB), poly (3,4-ethylenedioxy thiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, and mixtures thereof, but it is not limited thereto. For example, the hole injection material for the HIL 210 can include a compound in The HIL 314 can have a thickness of 10 to 100 Å.

The second HTL 334 of the second emitting part 330 has a single-layered structure. Namely, the first HTL 320 between the first EML being a blue EML and the first electrode 210 has a double-layered structure of the high refractive layer 322 and the low refractive layer 326, while the second HTL 334 between the second EML 332, which include the red and green EMLs 332a and 332b, and the CGL 360 has a single-layered structure.

The second HTL 334 can include a hole transporting material being at least one compound selected from the group consisting of N,N′-diphenyl-N,N′-bis(3-methylphenyl)-1,1′-biphenyl-4,4′-diamine (TPD), NPB (or NPD), 4,4′-bis(N-carbazolyl)-1,1′-biphenyl (CBP), poly[N,N′-bis(4-butylphenyl)-N,N′-bis(phenyl)-benzidine] (poly-TPD), (poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1, l′-biphenyl]-4-yl)-9,9-dimethyl-N-(4-(9-phenl-9H-carbazol-3-yl)phenyl)-9H-fluoren-2-amine, and mixtures thereof. In an aspect of the present disclosure, the second HTL 334 can include a compound in Formula 6.

The second HTL 334 can have a thickness of 50 to 200 Å, preferably 50 to 100 Å, or 100 to 150 Å. A thickness of the second HTL 334 can be smaller than that of the first HTL 320. For example, the second HTL 334 can have a thickness of 50 Å, 75 Å, 100 Å, 125 Å, 150 Å, 175 Å, or 200 Å.

In an aspect of the present disclosure, a refractive index of the hole transporting material of the second HTL 334 can be smaller than that of the first hole transporting material 324 and greater than that of the second hole transporting material 328.

Each of the first and second ETLs 316 and 336 can include an electron transporting material being selected from the group consisting of tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl)-4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), poly [9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), diphenyl-4-triphenylsilyl-phenylphosphine oxide (TSPO1), 2-[4-(9,10-Di-2-naphthalen2-yl-2-anthracen-2-yl)phenyl]-1-phenyl-1H-benzimidazole (ZADN), and mixtures thereof. Each of the first and second ETLs 316 and 336 can have a thickness of 100 to 500 Å, preferably 100 to 300 Å or 200 to 300 Å. For example, each of the first and second ETLs 316 and 336 can have a thickness of 150 Å, 175 Å, 200 Å, 225 Å, 250 Å, 275 Å, 300 Å. 350 Å, 375 Å, 400 Å, 425 Å, 450 Å, 475 Å, or 500 Å,

The EIL 338 can include an electron injection material being at least one of LiF, CsF, NaF, BaF₂, Liq, lithium benzoate, and sodium stearate. The EIL 338 can have a thickness of 1 to 30 Å, preferably 1 to 10 Å, or 5 to 20 Å. For example, the EIL 338 can have a thickness of 1 Å, 5 Å, 10 Å, 15 Å, 20 Å, 25 Å, or 30 Å.

The CGL 360 is positioned between the first and second emitting parts 310 and 330. Namely, the first and second emitting parts 310 and 330 are connected through the CGL 360. The CGL 360 can be a P-N junction CGL of an N-type CGL 362 and a P-type CGL 364.

The N-type CGL 362 is positioned between the first ETL 316 and the second HTL 334, and the P-type CGL 364 is positioned between the N-type CGL 362 and the second HTL 334.

The N-type CGL 362 can be an organic layer doped with an alkali metal, e.g., Li, Na, K and Cs, and/or an alkali earth metal, e.g., Mg, Sr, Ba and Ra. For example, the N-type CGL 362 can be formed of an N-type charge generation material including a host being the organic material, e.g., 4,7-dipheny-1,10-phenanthroline (Bphen) and MTDATA, a dopant being an alkali metal and/or an alkali earth metal, and the dopant can be doped with a weight % of 0.01 to 30.

The P-type CGL 364 can be formed of a P-type charge generation material including an inorganic material, e.g., tungsten oxide (WOx), molybdenum oxide (MoOx), beryllium oxide (Be₂O₃) and vanadium oxide (V₂O₅), an organic material, e.g., NPD, HAT-CN, F4TCNQ, TPD, TNB, TCTA and N,N′-dioctyl-3,4,9,10-perylenedicarboximide (PTCDI-C8).

As described above, the OLED D1 of the present disclosure can include the first emitting part 310 including the first EML 312 being a blue EML and the first HTL 320 and the second emitting part 330 including the red EML 332a and the green EML 332b and between the first emitting part 310 and the second electrode 230, and the first HTL 320 includes the high refractive layer 322 and the low refractive layer 326. Accordingly, in the OLED D1 of the present disclosure, the blue emitting efficiency is improved, and the color viewing angle is enhanced.

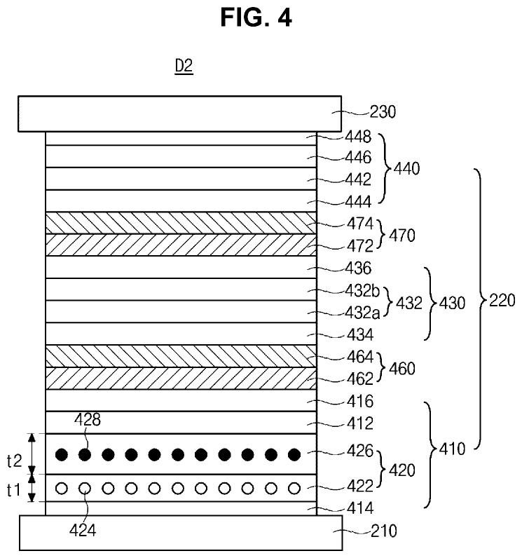

FIG. 4 is a schematic cross-sectional view illustrating another example of an OLED according to an embodiment of the present disclosure. The OLED configuration of FIG. 4 can be used as the OLED of FIGS. 1 and 2 or other figures or embodiments of the present disclosure.

As shown in FIG. 4, the OLED D2 includes the first and second electrodes 210 and 230, which face each other, and the organic emitting layer 220 therebetween, and the organic emitting layer 220 includes a first emitting part 410 including a first HTL 420, which includes a high refractive layer 422 and a low refractive layer 426, and a first EML 412, which is a blue EML, a second emitting part 430 including a second EML 432, which includes a red EML 432a and a green EML 432b, and positioned between the first emitting part 410 and the second electrode 230 and a third emitting part 440 including a third EML 442, which is a blue EML, and positioned between the second emitting part 430 and the second electrode 230.

The organic emitting layer 220 can further include a first CGL 460 between the first and second emitting parts 410 and 430 and a second CGL 470 between the second and third emitting parts 430 and 440.

The organic light emitting display device 100 includes the red, green and blue pixel regions RP, GP and BP, and the OLED D2 is positioned in each of the red, green and blue pixel regions RP, GP and BP and emits white light.

In the first emitting part 410, the first HTL 420 has a double-layered structure of the high refractive layer 422 and a low refractive layer 426, and the low refractive layer 426 is positioned between the high refractive layer 422 and the first EML 412. The low refractive layer 426 can contact the high refractive layer 422 and the first EML 412.

The high refractive layer 422 includes a first hole transporting material 424 having a first refractive index, and the low refractive layer 426 includes a second hole transporting material 428 having a second refractive index smaller than the first refractive index. A difference between the first and second refractive indexes can be 0.05 or more. In an aspect of the present disclosure, a difference between the first and second refractive indexes can be 0.05 or more and 0.25 or less, e.g., 0.09 or more and 0.25 or less, beneficially 0.1 or more and 0.25 or less, and more beneficially 0.15 or more and 0.25 or less. For example, the first refractive index can be in a range of 1.9 to 2.1, and the second refractive index can be in a range of 1.7 to 1.9.

In an aspect of the present disclosure, the first hole transporting material 424 can include at least one of the compound in Formula 1 and the compound in Formula 2, and the second hole transporting material 428 can include at least one of the compound in Formula 2, the compound in Formula 3, the compound in Formula 4 and the compound in Formula 5.

In an aspect of the present disclosure, the first hole transporting material 424 can be the compound in Formula 1. Namely, the high refractive layer 422 can be formed by only the compound in Formula 1.

In an aspect of the present disclosure, the first hole transporting material 424 can include the compound in Formula 1 and the compound in Formula 2. In this case, a weight % of the compound in Formula 1 can be equal to or greater than that of the compound in Formula 2. For example, a weight % ratio of the compound in Formula 2 to the compound in Formula 1 can be 5:5 to 9:1, e.g., 6:4, 7:3 or 8:2.

In an aspect of the present disclosure, the second hole transporting material 428 can include only the compound in Formula 3. Namely, the low refractive layer 426 can be formed by only the compound in Formula 3.

In an aspect of the present disclosure, the second hole transporting material 428 can include only the compound in Formula 4. Namely, the low refractive layer 426 can be formed by only the compound in Formula 4.

In an aspect of the present disclosure, the second hole transporting material 428 can include only the compound in Formula 5. Namely, the low refractive layer 426 can be formed by only the compound in Formula 5.

In an aspect of the present disclosure, the second hole transporting material 428 can include at least two of the compound in Formula 2, the compound in Formula 3, the compound in Formula 4 and the compound in Formula 5.

In an aspect of the present disclosure, the second hole transporting material 428 can include the compound in Formula 2 and the compound in Formula 4. In this case, a weight % of the compound in Formula 2 and a weight % of the compound in Formula 4 can be same or different. For example, the low refractive layer 426 can be formed by co-depositing the compound in Formula 2 and the compound in Formula 4.

In an aspect of the present disclosure, the second hole transporting material 428 can include the compound in Formula 4 and the compound in Formula 5. In this case, a weight % of the compound in Formula 4 and a weight % of the compound in Formula 5 can be same or different. For example, the low refractive layer 426 can be formed by co-depositing the compound in Formula 4 and the compound in Formula 5.

In an aspect of the present disclosure, the second hole transporting material 428 can include the compound in Formula 2 and the compound in Formula 5. In this case, a weight % of the compound in Formula 2 and a weight % of the compound in Formula 5 can be same or different. For example, the low refractive layer 426 can be formed by co-depositing the compound in Formula 2 and the compound in Formula 5.

In an aspect of the present disclosure, the first hole transporting material 424 can include at least one of the compound in Formula 1 and the compound in Formula 2, and the second hole transporting material 428 can include at least one of the compound in Formula 3, the compound in Formula 4 and the compound in Formula 5.

The high refractive layer 422 can have a first thickness t1, and the low refractive layer 426 can have a second thickness t2 being greater than the first thickness t1. The first thickness t1 of the high refractive layer 422 can be 10 to 49% of a thickness of the first HTL 420, and the second thickness t2 of the low refractive layer 426 can be 51 to 90% of the thickness of the first HTL 420. In an aspect of the present disclosure, the first thickness of the high refractive layer 422 can be 20 to 45%, e.g., 30 to 45%, of the thickness of the first HTL 420.

For example, the first thickness t1 can be 200 to 500 Å, e.g., 300 to 450 Å, and the second thickness t2 can be 500 to 800 Å, e.g., 550 to 700 Å. For example, the first thickness t1 can be 200 to 500 Å, (e.g., 250 to 450 Å, 300 to 450 Å, 250 to 400 Å, or 300 to 400 Å) and the second thickness t2 can be 500 to 800 Å, (e.g., 500 to 750 Å, 550 to 750 Å, or 550 to 700 Å).

The first EML 412 is a blue EML and can include a first blue host and a first blue dopant. The first blue dopant can include at least one of a fluorescent compound, a phosphorescent compound and a delayed fluorescent compound. In an aspect of the present disclosure, the first blue dopant can be a fluorescent compound.

For example, the first blue host can be selected from the above-mentioned blue host material, and the first blue dopant can be selected from the above-mentioned blue dopant material.

The first emitting part 410 can further include a first ETL 416 over the first EML 412. In addition, the first emitting part 410 can further include an HIL 414 under the first HTL 420.

For example, the first emitting part 410 can include the HIL 414, the first HTL 420, the first EML 412 and the first ETL 416 sequentially stacked on the first electrode 210, and the high refractive layer 422 can be disposed between the HIL 414 and the low refractive layer 426.

In the second emitting part 430, the green EML 432b can be positioned between the red EML 432a and the second electrode 230.

The red EML 432a can include a red host and a red dopant. The red host can include a p-type host and an n-type host, and the red dopant can include at least one of a fluorescent compound, a phosphorescent compound and a delayed fluorescent compound. In an aspect of the present disclosure, the red dopant can be a phosphorescent compound.

For example, the red host can include at least one selected from the above-mentioned red host materials, and the red dopant can be selected from the above-mentioned red dopant materials.

The green EML 432b can include a green host and a green dopant. The green host can include a p-type host and an n-type host, and the green dopant can include at least one of a fluorescent compound, a phosphorescent compound and a delayed fluorescent compound. In an aspect of the present disclosure, the green dopant can be a phosphorescent compound.

For example, the green host can include at least one selected from the above-mentioned green host materials, and the green dopant can be selected from the above-mentioned green dopant materials.

The second EML 430 can further include a yellow-green EML between the red and green EMLs 432a and 432b.

The yellow-green EML can include a yellow-green host and a yellow-green dopant. The yellow-green host can include a p-type host and an n-type host, and the yellow-green dopant can include at least one of a fluorescent compound, a phosphorescent compound and a delayed fluorescent compound. In an aspect of the present disclosure, the yellow-green dopant can be a phosphorescent compound.

The yellow-green host can be selected from the above-mentioned yellow-green host materials, and the yellow-green dopant can be selected from the above-mentioned yellow-green dopant materials.

The second emitting part 430 can further include a second HTL 434 under the second EML 432. The second emitting part 430 can further include a second ETL 436 over the second EML 432.

For example, the second emitting part 430 can include the second HTL 434, the second EML 432 and the second ETL 436 sequentially stacked on the first CGL 460.

The third EML 442 is a blue EML and can include a second blue host and a second blue dopant. The second blue dopant can include at least one of a fluorescent compound, a phosphorescent compound and a delayed fluorescent compound. In an aspect of the present disclosure, the second blue dopant can be a fluorescent compound.

For example, the second blue host can be selected from the above-mentioned blue host material, and the second blue dopant can be selected from the above-mentioned blue dopant material.

The third emitting part 440 can further include a third HTL 444 under the third EML 442. In addition, the third emitting part 440 can further include at least one of a third ETL 446 on the third EML 442 and an EIL 448 on the third ETL 446.

For example, the third emitting part 440 can include the third HTL 444, the third EML 442, the third ETL 446 and the EIL 448 sequentially stacked on the second CGL 470.

The HIL 414 can include the above-mentioned hole injection material and can have a thickness of 10 to 100 Å.

Each of the second HTL 434 of the second emitting part 430 and the third HTL 444 of the third emitting part 440 has a single-layered structure. Namely, the first HTL 420 between the first EML being a blue EML and the first electrode 210 has a double-layered structure of the high refractive layer 422 and the low refractive layer 426, while each of the second HTL 434 between the second EML 432, which include the red and green EMLs 432a and 432b, and the first CGL 460 and the third HTL 444 between the third EML 442, which is a blue EML, and the second CGL 470 has a single-layered structure.

Each of the second and third HTLs 434 and 444 can include the above-mentioned hole transporting material. In an aspect of the present disclosure, each of the second and third HTLs 434 and 444 can include the compound in Formula 6.

In an aspect of the present disclosure, a refractive index of each of a material of the second HTL 434 and a material of the third HTL 444 can be smaller than a refractive index of the first hole transporting material 424 and greater than a refractive index of the second hole transporting material 428.

Each of a thickness of the second HTL 434 and a thickness of the third HTL 444 can be smaller than a thickness of the first HTL 420. For example, the second HTL 434 can have a thickness of 50 to 200 Å, e.g., 50 to 100 Å, and the third HTL 444 can have a thickness of 700 to 800 Å. For example, the second HTL 434 can have a thickness of 50 Å, 75 Å, 100 Å, 125 Å, 150 Å, 175 Å, or 200 Å. For example, the third HTL 444 can have a thickness of 700 Å, 725 Å, 750 Å, 775 Å, or 800 Å.

Each of the first to third ETLs 416, 436 and 446 can include the above-mentioned electron transporting material and can have a thickness of 100 to 500 Å, preferably 100 to 300 Å. For example, each of the first to third ETLs 416, 436 and 446 can have a thickness of 100 Å, 150 Å, 175 Å, 200 Å, 225 Å, 250 Å, 275 Å, 300 Å, 350 Å, 375 Å, 400 Å, 425 Å. 450 Å, 475 Å, or 500 Å.

The EIL 448 can include an electron injection material being at least one of LiF, CsF, NaF, BaF₂, Liq, lithium benzoate, and sodium stearate. The EIL 448 can have a thickness of 1 to 30 Å, preferably 1 to 10 Å, or 5 to 20 Å. For example, the EIL 448 can have a thickness of 1 Å, 5 Å, 10 Å, 15 Å, 20 Å, 25 Å, or 30 Å.

The first CGL 460 is positioned between the first and second emitting parts 410 and 430. Namely, the first and second emitting parts 410 and 430 are connected through the first CGL 460. The first CGL 460 can be a P-N junction CGL of a first N-type CGL 462 and a first P-type CGL 464.

The first N-type CGL 462 is positioned between the first ETL 416 and the second HTL 434, and the first P-type CGL 464 is positioned between the first N-type CGL 462 and the second HTL 434.

The first N-type CGL 462 can be formed of the above-mentioned N-type charge generation material, and first P-type CGL 464 can be formed of the above-mentioned P-type charge generation material.

The second CGL 470 is positioned between the second and third emitting parts 430 and 440. Namely, the second and third emitting parts 430 and 440 are connected through the second CGL 470. The second CGL 470 can be a P-N junction CGL of a second N-type CGL 472 and a second P-type CGL 474.

The second N-type CGL 472 is positioned between the second ETL 436 and the third HTL 444, and the second P-type CGL 474 is positioned between the second N-type CGL 472 and the third HTL 444.

The second N-type CGL 472 can be formed of the above-mentioned N-type charge generation material, and second P-type CGL 474 can be formed of the above-mentioned P-type charge generation material.

As described above, the OLED D2 of the present disclosure includes the first emitting part 410 including the first EML 412 being a blue EML and the first HTL 420, the second emitting part 430 including the red EML 432a and the green EML 432b and between the first emitting part 410 and the second electrode 230 and the third emitting part 440 including a third EML 442 being a blue EML and between the second emitting part 430 and the second electrode 230, and the first HTL 420 includes the high refractive layer 422 and the low refractive layer 426. Accordingly, in the OLED D2 of the present disclosure, the blue emitting efficiency is improved, and the color viewing angle is enhanced.

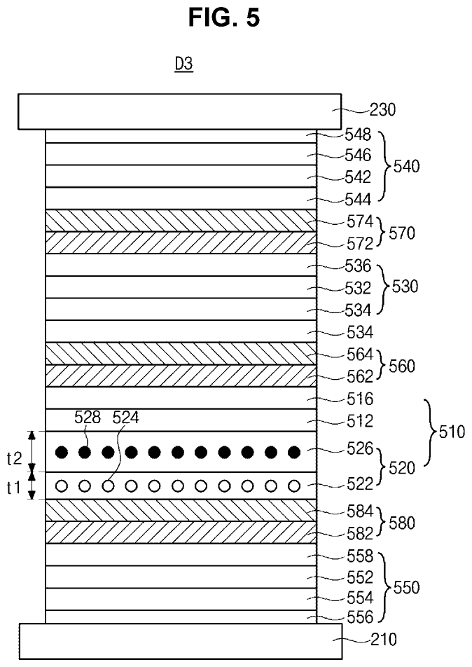

FIG. 5 is a schematic cross-sectional view illustrating another example of an OLED according to an embodiment of the present disclosure. The OLED configuration of FIG. 5 can be used as the OLED of FIGS. 1 and 2 or other figures or embodiments of the present disclosure.

As shown in FIG. 5, the OLED D3 includes the first and second electrodes 210 and 230, which face each other, and the organic emitting layer 220 therebetween, and the organic emitting layer 220 includes a first emitting part 510 including a first HTL 520, which includes a high refractive layer 522 and a low refractive layer 526, and a first EML 512, which is a blue EML, a second emitting part 530 including a second EML 532, which is a green EML, and positioned between the first emitting part 510 and the second electrode 230, a third emitting part 540 including a third EML 542, which is a blue EML, and positioned between the second emitting part 530 and the second electrode 230 and a fourth emitting part 550 including a fourth EML 552, which is a red EML, and positioned between the first emitting part 510 and the first electrode 210.

The organic emitting layer 220 can further include a first CGL 560 between the first and second emitting parts 510 and 530, a second CGL 570 between the second and third emitting parts 530 and 540 and a third CGL 580 between the first and fourth emitting parts 510 and 550.

The organic light emitting display device 100 includes the red, green and blue pixel regions RP, GP and BP, and the OLED D3 is positioned in each of the red, green and blue pixel regions RP, GP and BP and emits white light.

In the first emitting part 510, the first HTL 520 has a double-layered structure of the high refractive layer 522 and a low refractive layer 526, and the low refractive layer 526 is positioned between the high refractive 522 and the first EML 512. The low refractive layer 526 can contact the high refractive 522 and the first EML 512.

The high refractive layer 522 includes a first hole transporting material 524 having a first refractive index, and the low refractive layer 526 includes a second hole transporting material 528 having a second refractive index smaller than the first refractive index. A difference between the first and second refractive indexes can be 0.05 or more. In an aspect of the present disclosure, a difference between the first and second refractive indexes can be 0.05 or more and 0.25 or less, e.g., 0.09 or more and 0.25 or less, beneficially 0.1 or more and 0.25 or less, and more beneficially 0.15 or more and 0.25 or less. For example, the first refractive index can be in a range of 1.9 to 2.1, and the second refractive index can be in a range of 1.7 to 1.9.

In an aspect of the present disclosure, the first hole transporting material 524 can include at least one of the compound in Formula 1 and the compound in Formula 2, and the second hole transporting material 528 can include at least one of the compound in Formula 2, the compound in Formula 3, the compound in Formula 4 and the compound in Formula 5.

In an aspect of the present disclosure, the first hole transporting material 524 can be the compound in Formula 1. Namely, the high refractive layer 522 can be formed by only the compound in Formula 1.

In an aspect of the present disclosure, the first hole transporting material 524 can include the compound in Formula 1 and the compound in Formula 2. In this case, a weight % of the compound in Formula 1 can be equal to or greater than that of the compound in Formula 2. For example, a weight % ratio of the compound in Formula 2 to the compound in Formula 1 can be 5:5 to 9:1, e.g., 6:4, 7:3 or 8:2.

In an aspect of the present disclosure, the second hole transporting material 528 can include only the compound in Formula 3. Namely, the low refractive layer 526 can be formed by only the compound in Formula 3.

In an aspect of the present disclosure, the second hole transporting material 528 can include only the compound in Formula 4. Namely, the low refractive layer 526 can be formed by only the compound in Formula 4.

In an aspect of the present disclosure, the second hole transporting material 528 can include only the compound in Formula 5. Namely, the low refractive layer 526 can be formed by only the compound in Formula 5.

In an aspect of the present disclosure, the second hole transporting material 528 can include at least two of the compound in Formula 2, the compound in Formula 3, the compound in Formula 4 and the compound in Formula 5.

In an aspect of the present disclosure, the second hole transporting material 528 can include the compound in Formula 2 and the compound in Formula 4. In this case, a weight % of the compound in Formula 2 and a weight % of the compound in Formula 4 can be same or different. For example, the low refractive layer 526 can be formed by co-depositing the compound in Formula 2 and the compound in Formula 4.

In an aspect of the present disclosure, the second hole transporting material 528 can include the compound in Formula 4 and the compound in Formula 5. In this case, a weight % of the compound in Formula 4 and a weight % of the compound in Formula 5 can be same or different. For example, the low refractive layer 526 can be formed by co-depositing the compound in Formula 4 and the compound in Formula 5.

In an aspect of the present disclosure, the second hole transporting material 528 can include the compound in Formula 2 and the compound in Formula 5. In this case, a weight % of the compound in Formula 2 and a weight % of the compound in Formula 5 can be same or different. For example, the low refractive layer 526 can be formed by co-depositing the compound in Formula 2 and the compound in Formula 5.

In an aspect of the present disclosure, the first hole transporting material 524 can include at least one of the compound in Formula 1 and the compound in Formula 2, and the second hole transporting material 528 can include at least one of the compound in Formula 3, the compound in Formula 4 and the compound in Formula 5.

The high refractive layer 522 can have a first thickness t1, and the low refractive layer 526 can have a second thickness t2 being greater than the first thickness t1. The first thickness t1 of the high refractive layer 522 can be 10 to 49% of a thickness of the first HTL 520, and the second thickness t2 of the low refractive layer 526 can be 51 to 90% of the thickness of the first HTL 520. In an aspect of the present disclosure, the first thickness of the high refractive layer 522 can be 20 to 45%, e.g., 30 to 45%, of the thickness of the first HTL 520.

For example, the first thickness t1 can be 200 to 500 Å, e.g., 300 to 450 Å, and the second thickness t2 can be 500 to 800 Å, e.g., 550 to 700 Å. For example, the first thickness t1 can be 200 to 500 Å, (e.g., 250 to 450 Å, 300 to 450 Å, 250 to 400 Å, or 300 to 400 Å) and the second thickness t2 can be 500 to 800 Å, (e.g., 500 to 750 Å, 550 to 750 Å, or 550 to 700 Å).

The first EML 512 is a blue EML and can include a first blue host and a first blue dopant. The first blue dopant can include at least one of a fluorescent compound, a phosphorescent compound and a delayed fluorescent compound. In an aspect of the present disclosure, the first blue dopant can be a fluorescent compound.

For example, the first blue host can be selected from the above-mentioned blue host material, and the first blue dopant can be selected from the above-mentioned blue dopant material.

The first emitting part 510 can further include a first ETL 516 over the first EML 512.

For example, the first emitting part 510 can include the first HTL 520, the first EML 512 and the first ETL 516 sequentially stacked on the third CGL 580, and the high refractive layer 522 can be disposed between the HIL 556 and the low refractive layer 526, between the HIL 556 and the low refractive layer 522, between the fourth emitting part 540 and the low refractive layer 526 or between the third CGL 580 and the low refractive layer 526.

In the second emitting part 530, the green EML 532 can include a green host and a green dopant. The green host can include a p-type host and an n-type host, and the green dopant can include at least one of a fluorescent compound, a phosphorescent compound and a delayed fluorescent compound. In an aspect of the present disclosure, the green dopant can be a phosphorescent compound.

For example, the green host can include at least one selected from the above-mentioned green host materials, and the green dopant can be selected from the above-mentioned green dopant materials.

The second emitting part 530 can further include a second HTL 534 under the second EML 532. The second emitting part 530 can further include a second ETL 536 over the second EML 532.

For example, the second emitting part 530 can include the second HTL 534, the second EML 532 and the second ETL 536 sequentially stacked on the first CGL 560.

The third EML 542 is a blue EML and can include a second blue host and a second blue dopant. The second blue dopant can include at least one of a fluorescent compound, a phosphorescent compound and a delayed fluorescent compound. In an aspect of the present disclosure, the second blue dopant can be a fluorescent compound.

For example, the second blue host can be selected from the above-mentioned blue host material, and the second blue dopant can be selected from the above-mentioned blue dopant material.

The third emitting part 540 can further include a third HTL 544 under the third EML 542. In addition, the third emitting part 540 can further include at least one of a third ETL 546 on the third EML 542 and an EIL 548 on the third ETL 546.

For example, the third emitting part 540 can include the third HTL 544, the third EML 542, the third ETL 546 and the EIL 548 sequentially stacked on the second CGL 570.

In the fourth emitting part 550, the red EML 552 can include a red host and a red dopant. The red host can include a p-type host and an n-type host, and the red dopant can include at least one of a fluorescent compound, a phosphorescent compound and a delayed fluorescent compound. In an aspect of the present disclosure, the red dopant can be a phosphorescent compound.

For example, the red host can include at least one selected from the above-mentioned red host materials, and the red dopant can be selected from the above-mentioned red dopant materials.

The fourth emitting part 550 can further include a fourth HTL 554 under the fourth EML 552. In addition, the fourth emitting part 550 can further include at least one of an HIL 556 under the fourth HTL 554 and a fourth ETL 558 on the fourth EML 552.

The HIL 552 can include the above-mentioned hole injection material and can have a thickness of 10 to 100 Å. For example, the HIL 552 can have a thickness of 20 Å, 25 Å, 30 Å, 35 Å, 40 Å, 45 Å, 50 Å, 55 Å, 60 Å, 65 Å, 70 Å, 75 Å, 80 Å, 85 Å, 90 Å, 95 Å, or 100 Å.

Each of the second HTL 534 of the second emitting part 530, the third HTL 544 of the third emitting part 540 and the fourth HTL 554 of the fourth emitting part 550 has a single-layered structure. Namely, the first HTL 520 between the first EML being a blue EML and the first electrode 210 has a double-layered structure of the high refractive layer 522 and the low refractive layer 526, while each of the second HTL 534 between the second EML 532, which is a green EML, and the first CGL 560, the third HTL 544 between the third EML 542, which is a blue EML, and the second CGL 570 and the fourth HTL 554 between the fourth EML 552, which is a red EML, and the first electrode 210 has a single-layered structure.

Each of the second to fourth HTLs 534, 544 and 554 can include the above-mentioned hole transporting material. In an aspect of the present disclosure, each of the second to fourth HTLs 534, 544 and 554 can include the compound in Formula 6.

In an aspect of the present disclosure, a refractive index of each of a material of the second HTL 534, a material of the third HTL 544 and a material of the fourth HTL 554 can be smaller than a refractive index of the first hole transporting material 524 and greater than a refractive index of the second hole transporting material 528.

Each of a thickness of the second HTL 534, a thickness of the third HTL 544 and a thickness of the fourth HTL 554 can be smaller than a thickness of the first HTL 520. For example, each of the second and fourth HTLs 534 and 554 can have a thickness of 50 to 200 Å, e.g., 50 to 100 Å, and the third HTL 544 can have a thickness of 700 to 800 Å. For instance, each of the second and fourth HTLs 534 and 554 can have a thickness of 50 Å, 75 Å, 100 Å, 125 Å, 150 Å, 175 Å, or 200 Å. For instance, the third HTL 544 can have a thickness of 700 Å, 725 Å, 750 Å, 775 Å, or 800 Å.

Each of the first to fourth ETLs 516, 536, 546 and 558 can include the above-mentioned electron transporting material and can have a thickness of 100 to 500 Å, preferably 100 to 300 Å. For example, each of the first to fourth ETLs 516, 536, 546 and 558 can have a thickness of 100 Å, 150 Å, 175 Å, 200 Å, 225 Å, 250 Å, 275 Å, 300 Å, 350 Å, 375 Å, 400 Å, 425 Å, 450 Å, 475 Å, or 500 Å.

The EIL 548 can include an electron injection material being at least one of LiF, CsF, NaF, BaF₂, Liq, lithium benzoate, and sodium stearate. The EIL 548 can have a thickness of 1 to 30 Å, preferably 1 to 10 Å. For example, the EIL 548 can have a thickness of 1 Å, 5 Å, 10 Å, 15 Å, 20 Å, 25 Å, or 30 Å.

The first CGL 560 is positioned between the first and second emitting parts 510 and 530. Namely, the first and second emitting parts 510 and 530 are connected through the first CGL 560. The first CGL 560 can be a P-N junction CGL of a first N-type CGL 562 and a first P-type CGL 564.

The first N-type CGL 562 is positioned between the first ETL 516 and the second HTL 534, and the first P-type CGL 564 is positioned between the first N-type CGL 562 and the second HTL 534.

The first N-type CGL 562 can be formed of the above-mentioned N-type charge generation material, and first P-type CGL 564 can be formed of the above-mentioned P-type charge generation material.

The second CGL 570 is positioned between the second and third emitting parts 530 and 540. Namely, the second and third emitting parts 530 and 540 are connected through the second CGL 570. The second CGL 570 can be a P-N junction CGL of a second N-type CGL 572 and a second P-type CGL 574.

The second N-type CGL 572 is positioned between the second ETL 536 and the third HTL 544, and the second P-type CGL 574 is positioned between the second N-type CGL 572 and the third HTL 544.

The second N-type CGL 572 can be formed of the above-mentioned N-type charge generation material, and second P-type CGL 574 can be formed of the above-mentioned P-type charge generation material.

The third CGL 580 is positioned between the first and fourth emitting parts 510 and 550. Namely, the first and fourth emitting parts 510 and 550 are connected through the third CGL 580. The third CGL 580 can be a P-N junction CGL of a third N-type CGL 582 and a third P-type CGL 584.

The third N-type CGL 582 is positioned between the fourth ETL 558 and the first HTL 520, and the third P-type CGL 584 is positioned between the third N-type CGL 582 and the first HTL 520.

The third N-type CGL 582 can be formed of the above-mentioned N-type charge generation material, and third P-type CGL 584 can be formed of the above-mentioned P-type charge generation material.

As described above, the OLED D3 of the present disclosure includes the first emitting part 510 including the first EML 512 being a blue EML and the first HTL 520, the second emitting part 530 including the second EML 532 being a green EML and between the first emitting part 510 and the second electrode 230, the third emitting part 540 including a third EML 542 being a blue EML and between the second emitting part 530 and the second electrode 230 and the fourth emitting part 550 including the fourth EML 552 being a red EML and positioned between the first emitting part 510 and the first electrode 210, and the first HTL 520 includes the high refractive layer 522 and the low refractive layer 526. Accordingly, in the OLED D3 of the present disclosure, the blue emitting efficiency is improved, and the color viewing angle is enhanced.

### EXAMPLES

The following examples are not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### [OLED1]

An anode (ITO), an HIL, a first HTL, a blue EML, a first ETL, a first n-type CGL, a first p-type CGL, a second HTL, a red EML, a green EML, a second ETL, a second n-type CGL, a second p-type CGL, a third HTL, a blue EML, a third ETL, an EIL and a cathode (AL) were sequentially stacked to form a white OLED.

### 1. Comparative Example

### (1) Comparative Example 1 (Ref1)

A compound in Formula 6 was used to form the first HTL (1000 Å).

### (2) Comparative Example 2 (Ref2)

The second HTL was formed with a high refractive layer (30 Å) using the compound in Formula 1 (see above) and a low refractive layer (45 Å) using the compound in Formula 3 (see above).

### (3) Comparative Example 3 (Ref3)

The third HTL was formed with a high refractive layer (220 Å) using the compound in Formula 1 and a low refractive layer (340 Å) using the compound in Formula 3.

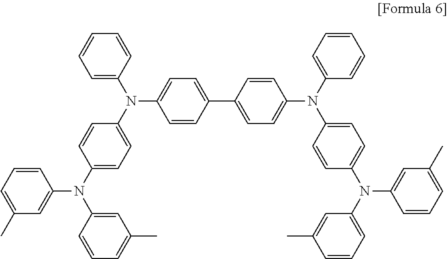 [SMILES: Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1]

### 2. Example 1 (Ex1)

The first HTL was formed with a high refractive layer (400 Å) using the compound in Formula 1 and a low refractive layer (600 Å) using the compound in Formula 3.

An efficiency (cd/A), a blue index (BI=cd/A(B)/By), a viewing angle (Δu′v′) and an external quantum efficiency of the OLED of Comparative Examples 1 to 3 and Example 1 were measured and listed in Table 2.

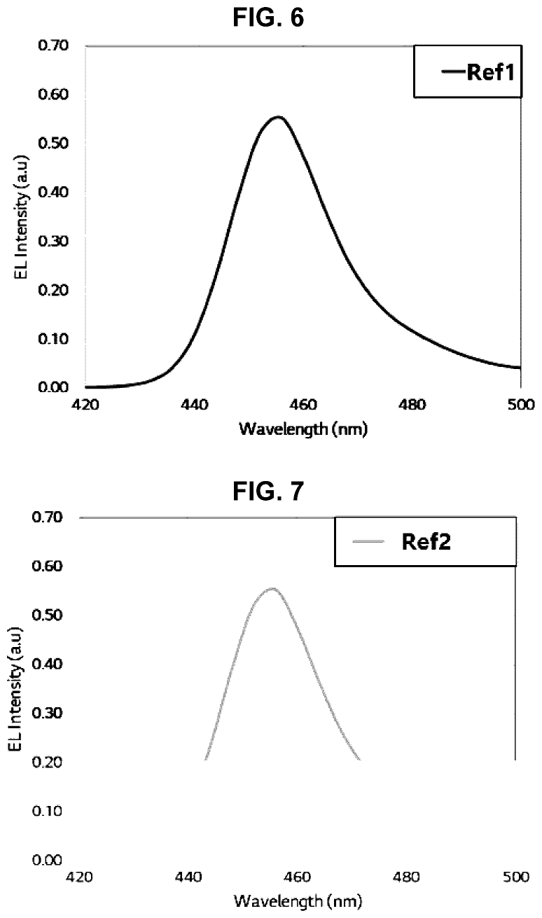

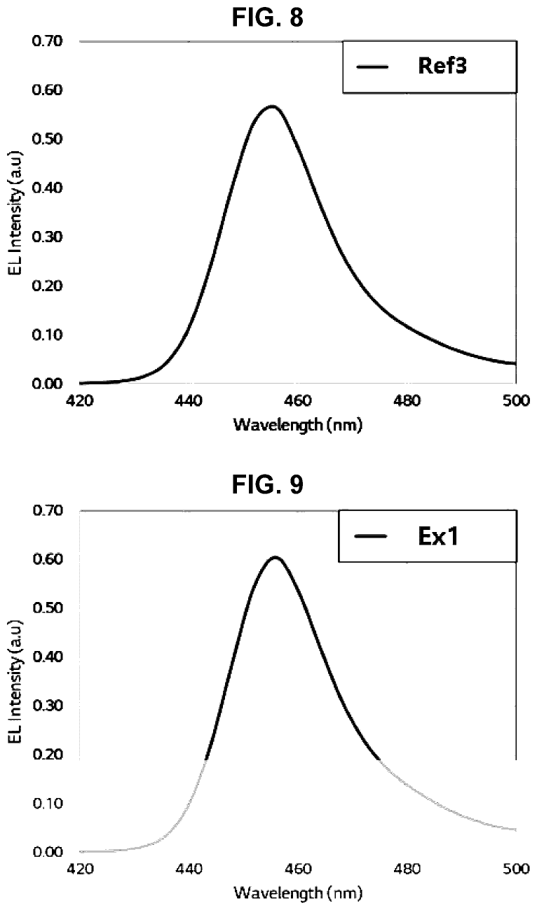

In addition, an EL spectrum of the OLED of Comparative Examples 1 to 3 and Example 1 were measured and shown in FIGS. 6 to 9, respectively.

TABLE 2

| | | Ref1 | Ref2 | Ref3 | Ex1 |
|---|---|---|---|---|---|
| cd/A | R | 8.93 | 8.91 | 8.69 | 9.46 |
| | G | 34.20 | 34.37 | 33.80 | 33.45 |
| | B | 5.41 | 5.42 | 5.42 | 5.93 |
| | W | 77.97 | 78.22 | 76.84 | 77.63 |
| BI | | 108.8 | 116.9 | 108.9 | 110.6 |
| Δu′v′ | | 0.020 | 0.020 | 0.019 | 0.011 |
| E.Q.E | | 41.4 | 41.4 | 41.3 | 43.4 |

As shown in Table 2, in comparison to the OLED of Comparative Example 1, in which each of the first to third HTLs has a single-layered structure, the emitting property of the OLED of Comparative Example 2, in which the second HTL between the red EML and the first CGL has a double-layered structure of the high and low refractive layers, and Comparative Example 3, in which the third HTL under the blue EML being closer to the cathode has a double-layered structure of the high and low refractive layers, is not improved.

However, in the OLED of Example 1, in which the first HTL under the blue EML being closer to the anode has a double-layered structure of the high and low refractive layers, the blue emitting efficiency is improved, and the viewing angle is significantly enhanced.

Namely, when the first HTL in the first emitting part, which is closer to the anode and includes the blue EML, has a double-layered structure of the high and low refractive layers, and each of the second HTL in the second emitting part, which includes the red and green EMLs, and the third HTL in the third emitting part, which is closer to the cathode and includes the blue EML, has a single-layered structure, the blue emitting efficiency and the viewing angle of the OLED and the organic light emitting display device are improved.

### 3. Example 2

In the OLED of Example 1, a thickness of the high refractive layer “HTL1-1” and a thickness of the low refractive layer “HTL1-2” are changed.

An efficiency (cd/A), a blue index (BI=cd/A(B)/By), a viewing angle (Δu′v′) and an external quantum efficiency of the OLED of Example 2 were measured and listed in Tables 3 and 4.

TABLE 3

| | | Thickness | | | | | |
|---|---|---|---|---|---|---|---|
| ETL1-2 | | 1000 | 900 | 800 | 700 | 600 | 500 |
| ETL1-1 | | 0 | 100 | 200 | 300 | 400 | 500 |
| cd/A | R | 7.97 | 8.20 | 8.49 | 8.81 | 9.13 | 9.42 |
| | G | 34.9 | 33.8 | 32.9 | 32.2 | 31.8 | 31.7 |
| | B | 5.58 | 5.68 | 5.78 | 5.85 | 5.87 | 5.84 |
| | W | 75.3 | 74.3 | 73.7 | 73.5 | 73.8 | 74.5 |

| | | | | | | |
|---|---|---|---|---|---|---|
| BI | 103.4 | 106.6 | 110.7 | 114.9 | 118.5 | 120.6 |
| Δu′v′ | 0.031 | 0.023 | 0.012 | 0.007 | 0.011 | 0.020 |
| E.Q.E | 40.3 | 40.8 | 41.3 | 42.0 | 42.6 | 43.0 |

TABLE 4

| | | Thickness | | | | |
|---|---|---|---|---|---|---|
| ETL1-2 | | 400 | 300 | 200 | 100 | 0 |
| ETL1-1 | | 600 | 700 | 800 | 900 | 1000 |
| cd/A | R | 9.64 | 9.76 | 9.78 | 9.68 | 9.49 |
| | G | 32.0 | 32.6 | 33.4 | 34.3 | 35.2 |
| | B | 5.76 | 5.65 | 5.55 | 5.48 | 5.45 |
| | W | 75.6 | 76.9 | 78.3 | 79.8 | 80.9 |

| | | | | | |
|---|---|---|---|---|---|
| BI | 120.7 | 119.0 | 115.9 | 112.4 | 109.3 |
| Δu′v′ | 0.026 | 0.028 | 0.026 | 0.023 | 0.019 |
| E.Q.E | 43.3 | 43.3 | 43.1 | 42.9 | 42.7 |

As shown in Tables 3 and 4, when the first HTL under the blue EML, which is closer to the anode, has a double-layered structure of the high refractive layer “HTL1-1” and low refractive layer “HTL1-2”, and a thickness of the high refractive layer “HTL1-1” is smaller than that of the low refractive layer “HTL1-2”, the blue emitting efficiency and the viewing angle of the OLED are improved. For example, the thickness of the high refractive layer “HTL1-1” can be in a range of 200 to 500 Å, e.g., 300 to 450 Å, and the thickness of the low refractive layer “HTL1-2” can be in a range of 500 to 800 Å, e.g., 550 to 700 Å.

### 4. Example 3

In the OLED of Example 1, a refractive index of the high refractive layer (350 Å) and a refractive index of the low refractive layer (650 Å) are changed.

An efficiency (cd/A), a blue index (BI=cd/A(B)/By), a viewing angle (Δu′v′) and an external quantum efficiency of the OLED of Example 3 were measured and listed in Table 5.

TABLE 5

| | | Refractive index | | | | | |
|---|---|---|---|---|---|---|---|
| HTL1-2 | | 1.75 | 1.80 | 1.85 | 1.90 | 1.95 | 2.00 |
| HTL1-1 | | n = 2.00 | | | | | |
| cd/A | R | 9.24 | 9.35 | 9.48 | 9.61 | 9.76 | 9.92 |
| | G | 31.2 | 32.1 | 32.9 | 33.6 | 34.2 | 34.8 |
| | B | 5.95 | 5.84 | 5.74 | 5.64 | 5.54 | 5.45 |
| | W | 73.0 | 74.9 | 76.6 | 78.4 | 80.0 | 81.5 |

| | | | | | | |
|---|---|---|---|---|---|---|
| BI | 120.1 | 117.8 | 115.7 | 113.7 | 112.0 | 110.5 |
| Δu′v′ | 0.014 | 0.014 | 0.016 | 0.019 | 0.023 | 0.027 |
| E.Q.E | 42.8 | 42.8 | 42.9 | 42.9 | 43.0 | 43.1 |

As shown in Table 5, when a difference between a refractive index of the high refractive layer “HTL1-1” and a refractive index of the low refractive layer “HTL1-2” is 0.1 or more, the blue emitting efficiency and the viewing angle of the OLED are improved. For example, a difference between a refractive index of the high refractive layer “HTL1-1” and a refractive index of the low refractive layer “HTL1-2” can be in a range of 0.1 to 0.25, e.g., 0.15 to 0.25.

### 5. Example 4

In the OLED of Example 1, a refractive index of the high refractive layer (400 Å) and a refractive index of the low refractive layer (600 Å) are changed.

An efficiency (cd/A), a blue index (BI=cd/A(B)/By), a viewing angle (Δu′v′) and an external quantum efficiency of the OLED of Example 3 were measured and listed in Table 6.

TABLE 6

| | | Refractive index | | | | | |
|---|---|---|---|---|---|---|---|
| HTL1-2 | | 1.70 | 1.75 | 1.80 | 1.85 | 1.90 | 1.95 |
| HTL1-1 | | n = 1.95 | | | | | |
| cd/A | R | 9.06 | 9.13 | 9.20 | 9.29 | 9.38 | 9.49 |
| | G | 30.8 | 31.8 | 32.8 | 33.7 | 34.5 | 35.2 |
| | B | 5.97 | 5.87 | 5.76 | 5.66 | 5.55 | 5.45 |
| | W | 72.0 | 73.8 | 75.7 | 77.5 | 79.2 | 80.9 |

| | | | | | | |
|---|---|---|---|---|---|---|
| BI | 121.2 | 118.5 | 115.9 | 113.5 | 111.3 | 109.3 |
| Δu′v′ | 0.013 | 0.011 | 0.011 | 0.012 | 0.015 | 0.019 |
| E.Q.E | 42.6 | 42.6 | 42.6 | 42.6 | 42.6 | 42.7 |

As shown in Table 6, when a difference between a refractive index of the high refractive layer “HTL1-1” and a refractive index of the low refractive layer “HTL1-2” is 0.1 or more, the blue emitting efficiency and the viewing angle of the OLED are improved. For example, a difference between a refractive index of the high refractive layer “HTL1-1” and a refractive index of the low refractive layer “HTL1-2” can be in a range of 0.1 to 0.25, e.g., 0.15 to 0.25.

### [OLED2]

An anode (ITO), an HIL, a first HTL, a blue EML, a first ETL, a first n-type CGL, a first p-type CGL, a second HTL, a red EML, a green EML, a second ETL, an EIL and a cathode (AL) were sequentially stacked to form a white OLED.

### 6. Comparative Example 4 (Ref4)

A compound in Formula 6 was used to form the first HTL (1000 Å).

### 7. Example 5 (Ex5)

The first HTL was formed with a high refractive layer (400 Å) using the compound in Formula 1 and a low refractive layer (600 Å) using the compound in Formula 3.

An efficiency (cd/A), a blue index (BI=cd/A(B)/By), a viewing angle (Δu′v′) and an external quantum efficiency of the OLED of Comparative Example 4 and Example 5 were measured and listed in Table 7.

TABLE 7

| | | Ref4 | Ex5 |
|---|---|---|---|
| cd/A | R | 11.1 | 9.98 |
| | G | 24.0 | 25.8 |
| | B | 3.56 | 3.91 |
| | W | 62.4 | 63.9 |
| BI | | 66.1 | 71.5 |
| Δu′v′ | | 0.048 | 0.033 |
| E.Q.E | | 34.5 | 34.9 |

As shown in Table 7, in comparison to the OLED of Comparative Example 4, in the OLED of Example 5, in which the first HTL under the blue EML being closer to the anode has a double-layered structure of the high and low refractive layers, the blue emitting efficiency is improved, and the viewing angle is significantly enhanced.

### [OLED3]

An anode (ITO), an HIL, a fourth HTL, a red EML a fourth ETL, a third n-type CGL, a third p-type CGL, a first HTL, a blue EML, a first ETL, a first n-type CGL, a first p-type CGL, a second HTL, a green EML, a second ETL, a second n-type CGL, a second p-type CGL, a third HTL, a blue EML, a third ETL, an EIL and a cathode (Al) were sequentially stacked to form a white OLED.

### 8. Comparative Example 5 (Ref5)

A compound in Formula 6 was used to form the first HTL (590 Å).

### 9. Example 6 (Ex6)

The first HTL was formed with a high refractive layer (240 Å) using the compound in Formula 1 and a low refractive layer (350 Å) using the compound in Formula 3.

An efficiency (cd/A), a blue index (BI=cd/A(B)/By), a viewing angle (Δu′v′) and an external quantum efficiency of the OLED of Comparative Example 5 and Example 6 were measured and listed in Table 8.

TABLE 8

| | | Ref5 | Ex6 |
|---|---|---|---|
| cd/A | R | 23.1 | 22.6 |
| | G | 52.0 | 49.6 |
| | B | 6.73 | 6.93 |
| | W | 115.3 | 112.0 |
| BI | | 101.8 | 110.6 |
| Δu′v′ | | 0.024 | 0.012 |
| E.Q.E | | 62.2 | 63.7 |

As shown in Table 8, in comparison to the OLED of Comparative Example 5, in the OLED of Example 6, in which the first HTL under the blue EML being closer to the anode has a double-layered structure of the high and low refractive layers, the blue emitting efficiency is improved, and the viewing angle is significantly enhanced.

### [OLED4]

An anode (ITO), an HIL, a first HTL, a blue EML, a first ETL, a first n-type CGL, a first p-type CGL, a second HTL, a red EML, a green EML, a second ETL, a second n-type CGL, a second p-type CGL, a third HTL, a blue EML, a third ETL, an EIL and a cathode (Al) were sequentially stacked to form a white OLED.

### 10. Comparative Example

### (1) Comparative Example 6 (Ref6)

The first HTL (850 Å) was formed by co-deposition of the compound in Formula 1 and the compound in Formula 5 with a weight % ratio of 8:2).

### (2) Comparative Example 7 (Ref7)

A lower layer (340 Å), which was formed by deposition of the compound in Formula 4, and an upper layer (560 Å), which was formed on the lower layer by co-deposition of the compound in Formula 1 and the compound in Formula 5 with a weight % ratio of 8:2, were formed to provide the first HTL having a double-layered structure.

### (3) Comparative Example 8 (Ref8)

A lower layer (340 Å), which was formed by deposition of the compound in Formula 5, and an upper layer (560 Å), which was formed on the lower layer by co-deposition of the compound in Formula 1 and the compound in Formula 5 with a weight % ratio of 8:2, were formed to provide the first HTL having a double-layered structure.

### 11. Example

### (1) Example 7 (Ex7)

A high refractive layer (340 Å), which was formed by deposition of the compound in Formula 1, and a low refractive layer (560 Å), which was formed on the high refractive layer by co-deposition of the compound in Formula 2 and the compound in Formula 4 with a weight % ratio of 5:5, were formed to provide the first HTL having a double-layered structure.

### (2) Example 8 (Ex8)

A high refractive layer (340 Å), which was formed by deposition of the compound in Formula 1, and a low refractive layer (560 Å), which was formed on the high refractive layer by co-deposition of the compound in Formula 4 and the compound in Formula 5 with a weight % ratio of 5:5, were formed to provide the first HTL having a double-layered structure.

### (3) Example 9 (Ex9)

A high refractive layer (340 Å), which was formed by deposition of the compound in Formula 1, and a low refractive layer (560 Å), which was formed on the high refractive layer by co-deposition of the compound in Formula 2 and the compound in Formula 5 with a weight % ratio of 5:5, were formed to provide the first HTL having a double-layered structure.

### (4) Example 10 (Ex10)

A high refractive layer (340 Å), which was formed by co-deposition of the compound in Formula 1 and the compound in Formula 2 with a weight % ratio of 7:3, and a low refractive layer (560 Å), which was formed on the high refractive layer by co-deposition of the compound in Formula 4 and the compound in Formula 5 with a weight % ratio of 5:5, were formed to provide the first HTL having a double-layered structure.

### (5) Example 11 (Ex11)

A high refractive layer (340 Å), which was formed by co-deposition of the compound in Formula 1 and the compound in Formula 2 with a weight % ratio of 7:3, and a low refractive layer (560 Å), which was formed on the high refractive layer by deposition of the compound in Formula 4, were formed to provide the first HTL having a double-layered structure.

An efficiency (cd/A), a blue index (BI=cd/A(B)/By), a viewing angle (Δu′v′), an external quantum efficiency and a blue lifespan (B-T95) of the OLED of Comparative Examples 6 to 8 and Examples 7 to 11 were measured and listed in Tables 9 and 10.

TABLE 9

| | | Ref6 | Ref7 | Ref8 |
|---|---|---|---|---|
| cd/A | B | 100.0% | 97.5% | 96.8% |
| | B Index | 100.0% | 95.8% | 95.1% |
| | W | 100.0% | 99.7% | 99.7% |
| CIE | Bx | — | +0.000 | +0.000 |
| | By | — | +0.001 | +0.000 |
| Δu′v′ | | — | +0.008 | +0.008 |
| EQE(%) | | 100.0% | 97.9% | 97.9% |
| B-T95 | | 100.0% | 100.0% | 100.0% |
| (@40° C., 40 J) | | | | |

TABLE 10

| | | Ref6 | Ex7 | Ex8 | Ex9 | Ex10 | Ex11 |
|---|---|---|---|---|---|---|---|
| cd/A | B | 100.0% | 102.8% | 103.7% | 102.9% | 103.5% | 102.9% |
| | B Index | 100.0% | 103.7% | 104.7% | 103.9% | 104.3% | 103.7% |
| | W | 100.0% | 99.0% | 98.1% | 99.2% | 97.8% | 97.5% |
| CIE | Bx | — | 0.000 | 0.000 | 0.000 | 0.000 | 0.000 |
| | By | — | 0.000 | 0.000 | 0.000 | 0.000 | 0.000 |

| | | | | | | |
|---|---|---|---|---|---|---|
| Δu′v′ | — | −0.002 | −0.003 | −0.001 | −0.002 | −0.003 |
| EQE(%) | 100.0% | 101.1% | 101.2% | 101.3% | 101.0% | 100.7% |
| B-T95 | 100.0% | 100.0% | 100.0% | 100.0% | 100.0% | 100.0% |
| (@40° C. 40 J) | | | | | | |

As shown in Table 10, in comparison to the OLED of Comparative Example 6, in which the first HTL has a single-layered structure, in the OLED of Examples 7 to 11, in which the first HTL has a double-layered structure of the high and low refractive layers, the emitting efficiency and the viewing angle are improved.

In addition, as shown in Tables 9 and 10, when the high refractive layer is disposed on the low refractive layer, the emitting efficiency and the viewing angle of the OLED are decreased. (see Ref7 and Ref8)

Namely, when the first HTL has a double-layered structure including the high refractive layer closer to the anode and the low refractive layer closer to the cathode, the emitting efficiency and the viewing angle of the OLED are increased.

### [OLED5]

An anode (ITO), an HIL, a first HTL, a blue EML, a first ETL, a first n-type CGL, a first p-type CGL, a second HTL, a red EML, a green EML, a second ETL, a second n-type CGL, a second p-type CGL, a third HTL, a blue EML, a third ETL, an EIL and a cathode (Al) were sequentially stacked to form a white OLED.

### 11. Comparative Example

### (1) Comparative Example 9 (Ref9)

A high refractive layer (340 Å), which was formed by deposition of the compound in Formula 1, and a low refractive layer (560 Å), which was formed on the high refractive layer by co-deposition of the compound in Formula 4 and the compound in Formula 5 with a weight % ratio of 5:5, were formed to provide the second HTL having a double-layered structure.

### (2) Comparative Example 10 (Ref10)

A high refractive layer (340 Å), which was formed by deposition of the compound in Formula 1, and a low refractive layer (560 Å), which was formed on the high refractive layer by co-deposition of the compound in Formula 4 and the compound in Formula 5 with a weight % ratio of 5:5, were formed to provide the third HTL having a double-layered structure.

An efficiency (cd/A), a blue index (BI=cd/A(B)/By), a viewing angle (Δu′v′) and an external quantum efficiency of the OLED of Comparative Examples 6, 9 and 10 and Example 8 were measured and listed in Table 11.

TABLE 11

| | | Ref6 | Ex8 | Ref9 | Ref10 |
|---|---|---|---|---|---|
| cd/A | B | 100.0% | 103.7% | 100.0% | 100.1% |
| | B Index | 100.0% | 104.7% | 100.1% | 100.8% |
| | W | 100.0% | 98.1% | 100.0% | 99.5% |
| CIE | Bx | — | 0.000 | 0.000 | 0.000 |
| | By | — | 0.000 | 0.000 | 0.000 |
| Δu′v′ | | — | −0.003 | 0.000 | 0.000 |
| E.Q.E(%) | | 100.0% | 101.2% | 100.1% | 100.6% |

As shown in Table 11, in comparison to the OLED of Comparative Example 6, in which each of the first to third HTLs has a single-layered structure, the emitting efficiency and the viewing angle of the OLED of Comparative Example 9, in which the second HTL under the red and green EMLs has a double-layered structure of the high and low refractive layers, and the OLED of Comparative Example 10, in which the second HTL under the blue EML, which is closer to the cathode, has a double-layered structure of the high and low refractive layers, are not increased.

However, in the OLED of Example 8, in which the first HTL under the blue EML, which is closer to the anode, has a double-layered structure of the high and low refractive layers, the emitting efficiency and the viewing angle are significantly increased.

Namely, in an OLED, in which the first HTL in the first emitting part, which is closer to the anode and includes the blue EML, has a double-layered structure of the high and low refractive layers and each of the second HTL in the second emitting part, which includes red and green EMLs, and the third HTL in the third emitting part, which is closer to the cathode and includes the blue EML, has a single-layered structure, the emitting efficiency and the viewing angle of the OLED and the organic light emitting display device are significantly increased.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

What is claimed is:

1. An organic light emitting diode, comprising:
a first electrode;
a second electrode facing the first electrode;
a first emitting part comprising a first hole transporting layer and a first emitting material layer and positioned between the first and second electrodes; and
a second emitting part comprising a second emitting material layer and positioned between the first emitting part and the second electrode,
wherein the first emitting material layer is a blue emitting material layer, and the second emitting material layer comprises at least one of a red emitting material layer and a green emitting material layer,
wherein the first hole transporting material layer comprises a high refractive layer having a first refractive index, and a low refractive layer having a second refractive index and positioned between the high refractive layer and the first emitting material layer, and
wherein the second refractive index is smaller than the first refractive index.

2. The organic light emitting diode according to claim 1, wherein a difference between the first refractive index and the second refractive index is 0.05 or more.

3. The organic light emitting diode according to claim 1, wherein the high refractive layer comprises at least one of a compound in Formula 1 and a compound in Formula 2, and the low refractive layer comprises at least one of a compound in Formula 2, a compound in Formula 3, a compound in Formula 4 and a compound in Formula 5:

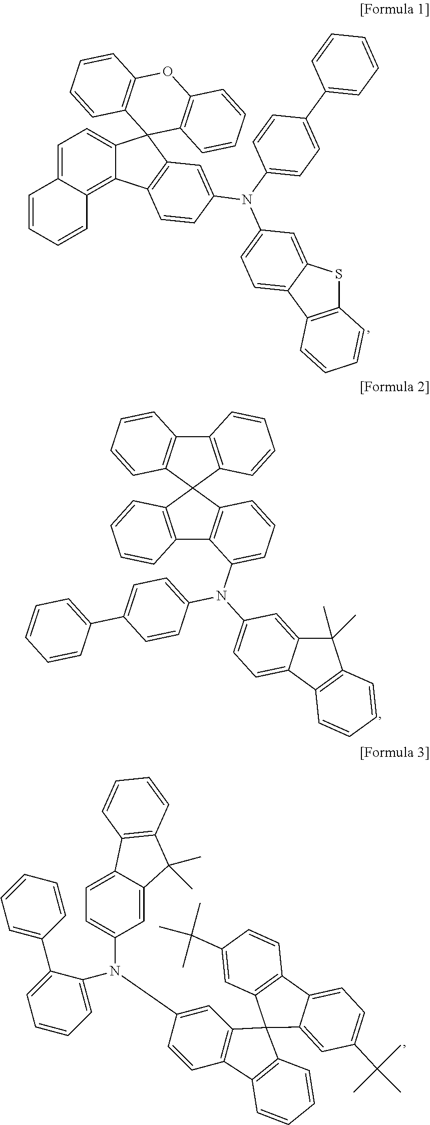 [SMILES: c1ccc(-c2ccc(N(c3ccc4c(c3)C3(c5ccccc5Oc5ccccc53)c3ccc5ccccc5c3-4)c3ccc4c(c3)sc3ccccc34)cc2)cc1 ; CC1(C)c2ccccc2-c2ccc(N(c3ccc(-c4ccccc4)cc3)c3cccc4c3-c3ccccc3C43c4ccccc4-c4ccccc43)cc21 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

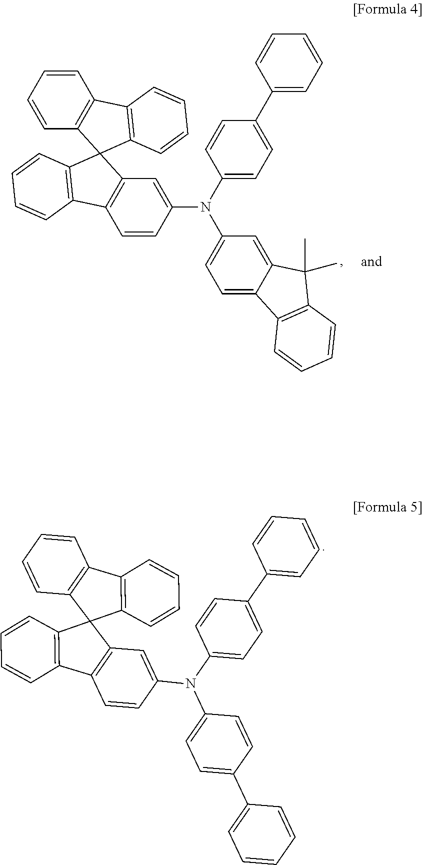 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(N(c3ccc(-c4ccccc4)cc3)c3ccc4c(c3)C3(c5ccccc5-c5ccccc53)c3ccccc3-4)cc2)cc1]

4. The organic light emitting diode according to claim 3, wherein the low refractive layer comprises at least one of the compound in Formula 3, the compound in Formula 4 and the compound in Formula 5.

5. The organic light emitting diode according to claim 3, wherein the high refractive layer comprises the compound in Formula 1 and the compound in Formula 2, and a weight % of the compound in Formula 1 is equal to or greater than a weight % of the compound in Formula 2.

6. The organic light emitting diode according to claim 1, wherein the high refractive layer has a first thickness, and the low refractive layer has a second thickness greater than the first thickness.

7. The organic light emitting diode according to claim 6, wherein the first thickness is about 20 to 45% of a thickness of the first hole transporting layer.

8. The organic light emitting diode according to claim 1, wherein the second emitting part further comprises a second hole transporting layer under the second emitting material layer, and
wherein the second hole transporting layer has a single-layered structure.

9. The organic light emitting diode according to claim 8, wherein a refractive index of a hole transporting material of the second hole transporting layer is smaller than the first refractive index and is greater than the second refractive index.

10. The organic light emitting diode according to claim 1, further comprising:
a third emitting part comprising the third emitting material layer and positioned between the second emitting part and the second electrode, the third emitting material layer being a blue emitting material layer,
wherein the second emitting material layer comprises the red emitting material layer and the green emitting material layer.

11. The organic light emitting diode according to claim 10, wherein the second emitting material layer further comprises a yellow-green emitting material layer between the red and green emitting material layers.

12. The organic light emitting diode according to claim 10, wherein the second emitting part further comprises a second hole transporting layer under the second emitting material layer, and the third emitting part further comprises a third hole transporting layer under the third emitting material layer, and
wherein each of the second and third hole transporting layers has a single-layered structure.

13. The organic light emitting diode according to claim 12, wherein each of a refractive index of a hole transporting material of the second hole transporting layer and a refractive index of a hole transporting material of the third hole transporting layer is smaller than the first refractive index and is greater than the second refractive index.

14. The organic light emitting diode according to claim 1, further comprising:
a third emitting part comprising the third emitting material layer and positioned between the second emitting part and the second electrode, the third emitting material layer being a blue emitting material layer, and
a fourth emitting part comprising a fourth emitting material layer and positioned between the first emitting part and the first electrode,
wherein the second emitting material layer comprises the green emitting material layer, and the fourth emitting material layer is a red emitting material layer.

15. The organic light emitting diode according to claim 14, wherein the second emitting part further comprises a second hole transporting layer under the second emitting material layer, and the third emitting part further comprises a third hole transporting layer under the third emitting material layer,
wherein the fourth emitting part further comprises a fourth hole transporting layer under the fourth emitting material layer, and
wherein each of the second to fourth hole transporting layers has a single-layered structure.

16. The organic light emitting diode according to claim 15, wherein each of a refractive index of a hole transporting material of the second hole transporting layer, a refractive index of a hole transporting material of the third hole transporting layer and a refractive index of a hole transporting material of the fourth hole transporting layer is smaller than the first refractive index and is greater than the second refractive index.

17. The organic light emitting diode according to claim 1, wherein the second emitting material layer comprises the red emitting material layer and the green emitting material layer, and the second emitting material layer further comprises a yellow-green emitting material layer between the red and green emitting material layers.

18. An organic light emitting device, comprising:
a substrate; and
the organic light emitting diode of claim 1 disposed over the substrate.

19. The organic light emitting device according to claim 18, wherein the high refractive layer comprises at least one of a compound in Formula 1 and a compound in Formula 2, and the low refractive layer comprises at least one of a compound in Formula 2, a compound in Formula 3, a compound in Formula 4 and a compound in Formula 5:

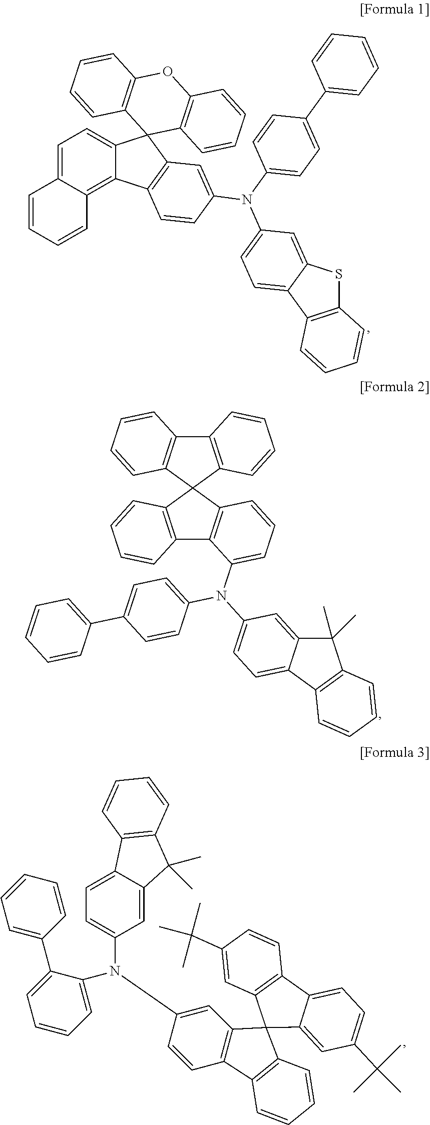 [SMILES: c1ccc(-c2ccc(N(c3ccc4c(c3)C3(c5ccccc5Oc5ccccc53)c3ccc5ccccc5c3-4)c3ccc4c(c3)sc3ccccc34)cc2)cc1 ; CC1(C)c2ccccc2-c2ccc(N(c3ccc(-c4ccccc4)cc3)c3cccc4c3-c3ccccc3C43c4ccccc4-c4ccccc43)cc21 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

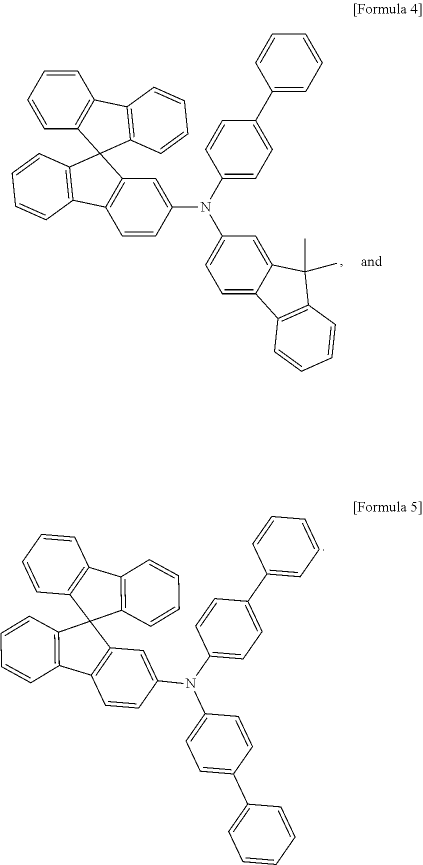 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(N(c3ccc(-c4ccccc4)cc3)c3ccc4c(c3)C3(c5ccccc5-c5ccccc53)c3ccccc3-4)cc2)cc1]

20. The organic light emitting device according to claim 18, wherein the high refractive layer has a first thickness, and the low refractive layer has a second thickness greater than the first thickness.
